(19) United States
(12) Patent Application Publication
(10) Pub. No.: US 2023/0275444 A1
(43) Pub. Date: Aug. 31, 2023

(54) MAGNET COUPLING ASSEMBLY

(71) Applicant: MILWAUKEE ELECTRIC TOOL CORPORATION, Brookfield, WI (US)

(72) Inventors: Kyle Reeder, Waukesha, WI (US); Isabel M. Lloyd, West Allis, WI (US); Caroline Fox, Richfield, WI (US); Casey L. Bonath, Milwaukee, WI (US); Matthew Post, Milwaukee, WI (US); John S. Scott, Brookfield, WI (US); Gareth Mueckl, Milwaukee, WI (US); Matthew N. Thurin, Richfield, WI (US); Kevin D. White, Milwaukee, WI (US); Brijeshkumar K. Meghpara, Germantown, WI (US); Marc S. D'Antuono, Whitefish Bay, WI (US); Harold A. Morrow, JR., Waukesha, WI (US); Keith G. Koch, Kenosha, WI (US); Jacob D. Rosenthal, Brookfield, WI (US); James Dykstra, Milwaukee, WI (US); David L. Nomura, Shorewood, WI (US)

(21) Appl. No.: 18/171,720

(22) Filed: Feb. 21, 2023

Related U.S. Application Data
(60) Provisional application No. 63/313,843, filed on Feb. 25, 2022.

(51) Int. Cl. H02J 7/00; H05K 7/18; H05K 5/02

(52) U.S. Cl. CPC H02J 7/0045; H05K 7/18; H05K 5/0204

(57) ABSTRACT

A charging station includes a housing defining a forward side and a rear side opposite the forward side and a charging port disposed on the housing. The charging port includes a battery receptacle to receive and charge a battery pack. The charging station also includes a magnet assembly disposed on the rear side of the housing. The magnet assembly is configured to support the housing from a mating surface.

### CROSS REFERENCE TO RELATED APPLICATION

This application claims the benefit of co-pending U.S. Provisional Patent Application No. 63/313,843, filed on Feb. 25, 2022, the entire content of which is incorporated herein by reference.

### BACKGROUND

The present disclosure relates generally to gang box charging systems, devices, and related methods.

### SUMMARY

In one embodiment, the invention provides a charging station including a housing defining a forward side and a rear side opposite the forward side and a charging port disposed on the housing. The charging port includes a battery receptacle to receive and charge a battery pack. The charging station also includes a magnet assembly disposed on the rear side of the housing. The magnet assembly is configured to support the housing from a mating surface.

In another embodiment, the invention provides a magnet assembly to couple a module to a mating surface. The magnet assembly includes a magnet, a billet, and an actuator moveable between a first position, in which the billet engages the mating surface to support the charging station and a second position, in which the billet is disengaged from the mating surface.

In another embodiment, the invention provides a charging station including a housing defining a front housing and a rear housing opposite the front housing and a charging port disposed on the housing. The charging port includes a battery receptacle configured to receive and charge a battery pack. The charging station also includes a magnet assembly configured to support the housing from a mating surface. The magnet assembly includes a magnet and an actuator moveable between a first position, in which the magnet assembly engages the mating surface to support the charging station and a second position, in which the magnet assembly is disengaged from the mating surface.

Other features and aspects of the disclosure will become apparent by consideration of the following detailed description and accompanying drawings.

### BRIEF DESCRIPTION OF THE DRAWINGS

FIG. 1 is a perspective view of a charging station for a gang box according to one embodiment of the invention.

FIG. 2 is a perspective view of a mounting plate for the charging station of FIG. 1.

FIG. 3 is a rear perspective view of a housing of the charging station of FIG. 1.

FIG. 4 is a close-up perspective view of the charging station of FIG. 1.

FIG. 5 is a front view of the charging station of FIG. 1.

FIG. 6 is another perspective view of the charging station of FIG. 1.

FIG. 7 is another perspective view of the charging station of FIG. 1.

FIG. 8 is a front view of the charging station of FIG. 1 in a closed configuration.

FIG. 9 is a perspective view of a charging station for a gang box according to another embodiment of the invention.

FIG. 10 is a close-up perspective view of the charging station of FIG. 9.

FIG. 11 is a front perspective view of a charging station for a gang box.

FIG. 12 is a front perspective view of the charging station of FIG. 11 with battery packs removed.

FIG. 13 is a rear perspective view of the charging station of FIG. 12.

FIG. 14 is a front view of the charging station of FIG. 12.

FIG. 15 is a front perspective view of the charging station of FIG. 12 with a portion removed.

FIG. 16 is a first front perspective view of a charging station for a gang box according to another embodiment of the invention.

FIG. 17 is a second front perspective view of the charging station of FIG. 16.

FIG. 18 is a rear perspective view of the charging station of FIG. 16.

FIG. 19 is a front perspective view of a charging station for a gang box according to another embodiment of the invention.

FIG. 20 is a perspective view of a port according to another embodiment of the invention.

FIG. 21 is a perspective view of a port according to another embodiment of the invention.

FIG. 22 is a side view of the charging station of FIG. 12 mounted to a gang box in a first position.

FIG. 23 is a side view of the charging station of FIG. 12 mounted to a gang box in a second position.

FIG. 24 is a side view of the charging station of FIG. 12 mounted to a gang box in a third position.

FIG. 25 is a perspective view of a portion of a charging station for a gang box according to another embodiment with a magnet assembly.

FIG. 26 is a rear view of the charging station of FIG. 25 with the magnet assembly in a first position.

FIG. 27 is a top view of the charging station of FIG. 26.

FIG. 28 is a rear view of the charging station of FIG. 25 with the magnet assembly in a second position.

FIG. 29 is a top view of the charging station of FIG. 28.

FIG. 30 is a perspective view of a portion of a charging station for a gang box according to another embodiment with a magnet assembly.

FIG. 31 is a perspective view of the charging station of FIG. 30 with a portion removed.

FIG. 32 is a top view of the charging station of FIG. 30 with the magnet assembly in a first position.

FIG. 33 is a top view of the charging station of FIG. 30 with the magnet assembly in a second position.

FIG. 34 is a top view of the charging station of FIG. 30 with the magnet assembly in a third position.

FIG. 35 is an exploded view of a magnet assembly.

FIG. 36 is a plan view of the magnet assembly of FIG. 35 positioned within a housing of a charging station.

FIG. 37 is a first perspective view of a portable charging station.

FIG. 38 is a second perspective view of the portable charging station of FIG. 37.

FIG. 39 is a perspective view of a docking assembly for the portable charging station of FIG. 37.

FIG. 40 is a close-up view of the docking station of FIG. 39 with a portable charging station undocked.

FIG. 41 is a cross-sectional view of the docking assembly of FIG. 39 with the portable charging station in a first position.

FIG. 42 is a cross-sectional view of the docking assembly of FIG. 39 with the portable charging station in a second position.

FIG. 43 is a cross-sectional view of the docking assembly of FIG. 39 with the portable charging station in a third position.

FIG. 44 is a schematic view of a circuit for use with the portable charging station of FIG. 37.

FIG. 45 is a plan view of a locking system for the portable charging station of FIG. 37.

FIG. 46 is a top view of the portable charging station of FIG. 37.

FIG. 47 is a perspective view of a charging station according to another embodiment of the invention.

FIG. 48 is a front view of the charging station of FIG. 47.

FIG. 49 is a perspective view of a portion of the charging station of FIG. 47 with a portion removed.

FIG. 50 is a perspective view of a power hub for use with the charging station of FIG. 47

FIG. 51 is another perspective view of the power hub of FIG. 49.

FIG. 52 is a rear perspective view of a charging station for a gang box according to another embodiment with a magnet assembly.

FIG. 53 is a rear view of the charging station of FIG. 52 with portions removed.

FIG. 54 is a top view of the charging station of FIG. 52 with the magnet assembly in a mounting position.

FIG. 55 is a schematic view of the charging station of FIG. 53.

FIG. 56 is a top view of the charging station of FIG. 52 with the magnet assembly in a dismount position.

FIG. 57 is a schematic view of the charging station of FIG. 55.

### DETAILED DESCRIPTION

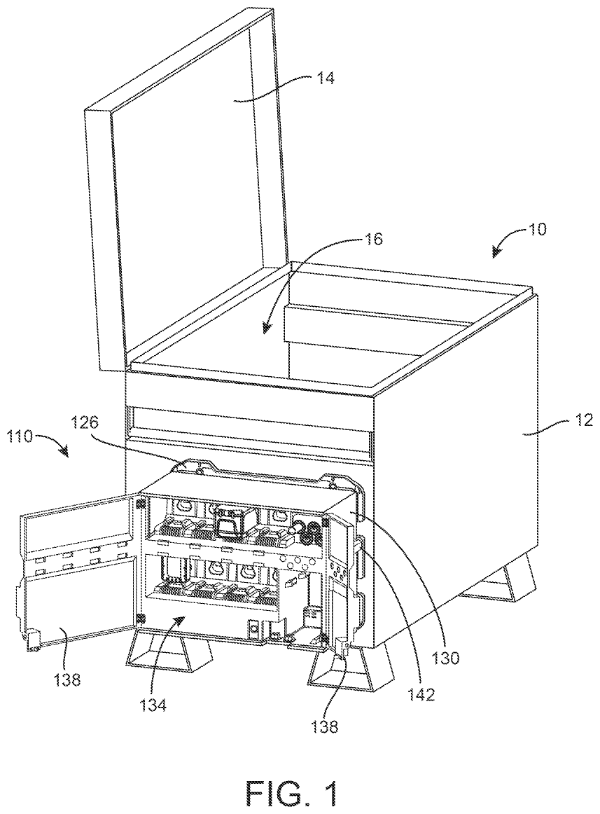

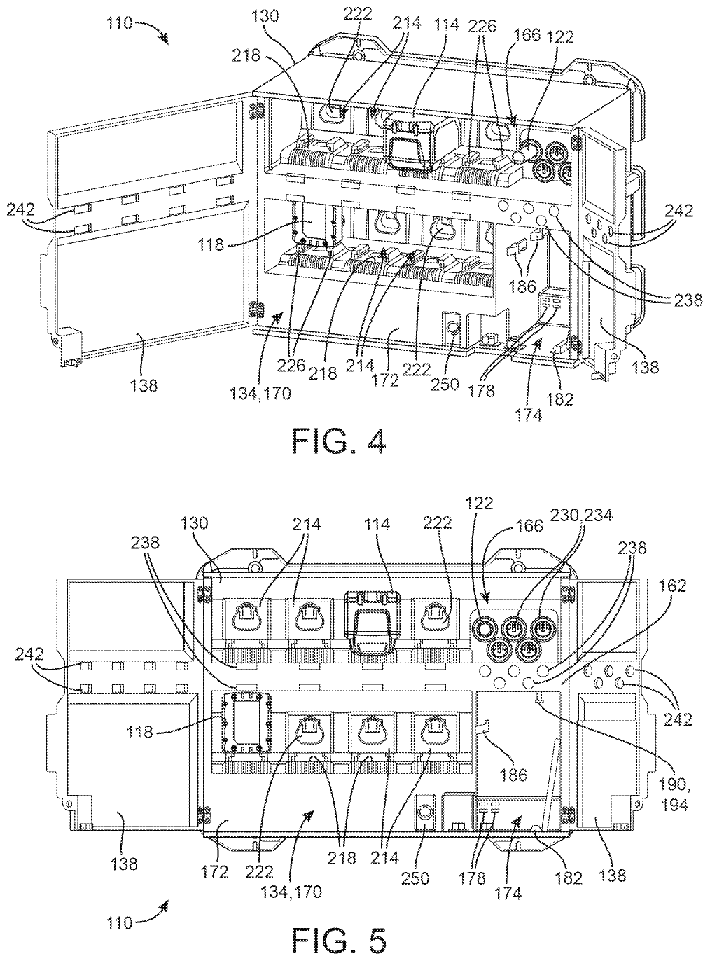

FIG. 1 illustrates a charging station 110 for a gang box 10. The charging station 110 is configured to store and charge multiple battery packs. In the illustrated embodiment, the charging station 110 is configured to store and charge first battery packs 114, second battery packs 118, or third battery packs 122 (FIG. 4). The charging station 110 is positioned externally relative to the gang box 10 to provide more free space within the gang box 10 and reduce the heating produced by the charging station 110 due to charging. The gang box 10 includes a housing 12 that defines an interior 16 and a lid 18 that is coupled to the housing 12 to selectively enclose the interior 16 of the gang box 10. The charging station 110 is coupled to an external side of the gang box 10 with a mounting plate 126. The charging station 110 includes a housing 130 that defines an interior 134 of the charging station 110 and two doors 138 coupled to the housing 130 that selectively enclose the interior 134 of the housing 130. Handles 142 are coupled to the exterior of the housing 130 to facilitate transporting the charging station 110. In the illustrated embodiment, the housing 130 is made of a plastic material. In other embodiments, the housing 130 may be made from metal or other materials.

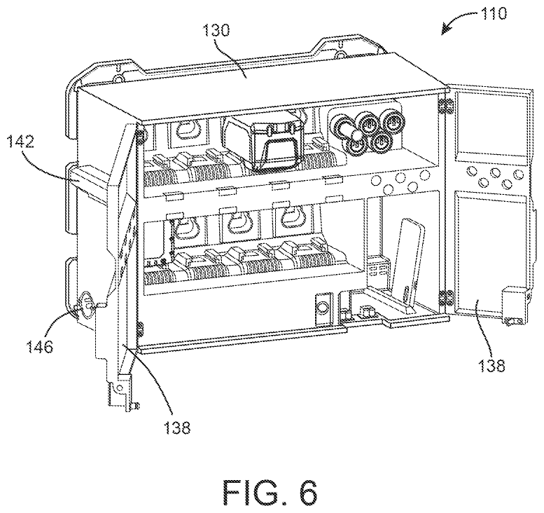

The housing 130 also includes a power receptacle 146 (FIG. 6) on an exterior side of the housing 130 to provide power to the charging station 110. In the illustrated embodiment, the power receptacle 146 is a male A/C plug configured to couple to a female power cord to transfer power to the charging station 110.

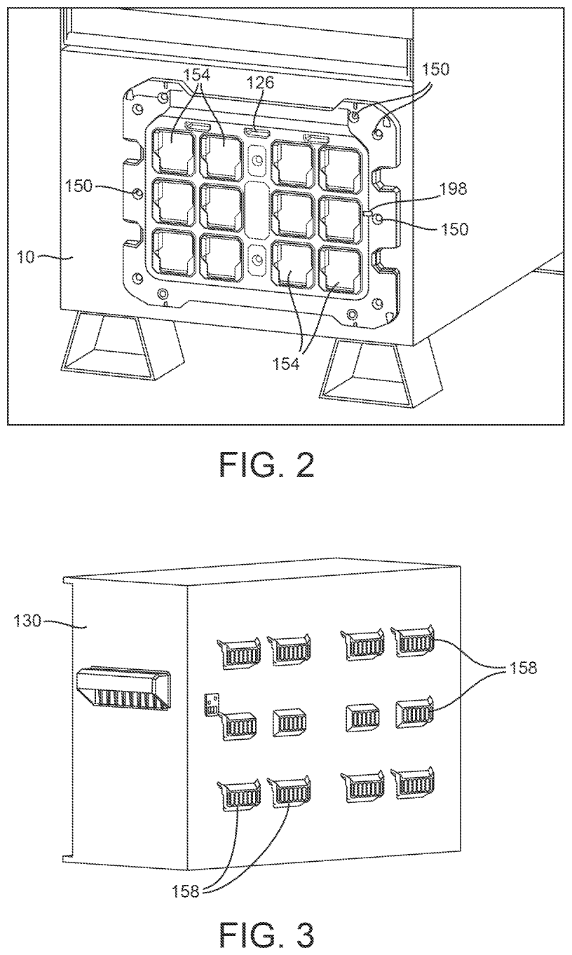

With reference to FIG. 2, the mounting plate 126 includes a plurality of mounting apertures 150 that are configured to receive a fastener to couple the mounting plate 126 to the gang box 10. The mounting plate 126 also includes a plurality of receptacles 154 that correspond to a plurality of projections 158 (FIG. 3) on the back of the housing 130 of the charging station 110. The projections 158 align and couple to the receptacles 154 to secure the charging station 110 above a surface. The charging station 110 is selectively coupled to the mounting plate 126. In other words, the charging station 110 may be removed from the mounting plate 126 and transported to another location.

With reference to FIGS. 4 and 5, the housing 130 includes a shelf 162 that divides the interior 134 into a top portion 166 and a bottom portion 170. The bottom portion 170 includes a compartment 172 and a storage area 174. The compartment 172 includes the control electronics for the charging station 110. The control electronics may include at least one controller or printed circuit board (PCB) that controls operation of the charging station 110. The storage area 174 includes a plurality of USB ports 178, a rib 182, storage hooks 186, and a locking mechanism 190. The USB ports 178 may be either USB-A or USB-C port. In other embodiments, the USB ports 178 may be other USB types. The USB ports 178 may be configured to charge phones, tablets, or the like through a charging cable. In the illustrated embodiment, the charging station 110 includes four USB ports 178. The rib 182 is positioned on a bottom surface of the housing 130. The rib 182 is configured to hold a phone or tablet in an upright position to free up space within the interior 134 of the housing 130. The storage hooks 186 allow a user to place equipment or cables above the bottom surface of the housing 130. The locking mechanism 190 includes a deadbolt 194 that is slidable along a track to lock the charging station 110 to the mounting plate 126. A user can slide the deadbolt 194 towards the mounting plate 126. The deadbolt 194 aligns with a slot 198 (FIG. 2) on the mounting plate 126. When the deadbolt 194 is received in the slot 198, the charging station 110 is inhibited from being removed from the mounting plate 126. The locking mechanism 190 can be utilized at the end of a workday to ensure the charging station 110 is not stolen. The locking mechanism 190 is only accessible when the doors 138 are in an open configuration. As shown in FIG. 8, when the doors 138 are in a closed configuration, they define a recess 202 with a clasp 206. A pad lock 210 may be coupled to the clasp 206 to prevent unwanted access to the interior 134 of the housing 130. In other embodiments, a keypad lock may be positioned in the recess 202 to lock the doors 138 in the closed configuration.

The charging station 110 also includes a plurality of charging ports 214 disposed in the top and bottom portions 166, 170 of the interior 134. Each charging port 214 includes a first receptacle 218 to receive the first battery pack 114 and a second receptacle 222 that is different from the first receptacle 218 to receive the second battery pack 118. As such, each charging port 214 may alternatively receive the first or the second battery pack 114, 118. When a battery pack is received in one of the charging ports 214, power is transferred from the control electronics to the battery packs 114, 118. In some embodiments, each charging port 214 may include a dedicated PCB to control the charging at the port 214. In other embodiments, a PCB board may control two or more charging ports 214.

In the illustrated embodiment, the bottom portion 170 of the housing 130 includes four charging ports 214 and the top portion 166 includes four charging ports 214. Multiple battery packs may be coupled to multiple charging ports 214 simultaneously. In other embodiments, the top and bottom portions 166, 170 of the housing 130 may include more than or less than four charging ports 214. The charging ports 214 also include guide rails 226 that guide the battery packs 114, 118 into the first or second receptacles 218, 222. In some embodiments, four of the charging ports 214 charge simultaneously while four of the charging ports 214 charge in sequential order. In other embodiments, all the charging ports 214 may charge simultaneously or sequentially.

The top portion 166 of the interior 134 also includes a plurality of secondary charging ports 230. The secondary charging ports 230 are configured to receive and charge the third battery pack 122. Each secondary charging port 230 includes a third battery receptacle 234 that is different from the first and second battery receptacles 218, 222. In the illustrated embodiment, the top portion 166 of the interior 134 includes five secondary charging ports 230. In other embodiments, the top portion 166 of the interior 134 may include more than or less than five secondary charging ports 230. In some embodiments, each secondary charging port 230 may include a dedicated PCB board to control charging to the port 230. In further embodiments, the secondary charging ports 230 may be removed from the charging station 110 in favor of more storage area or more charging ports 214.

In the illustrated embodiment, each of the charging ports 214 and the secondary charging ports 230 include a dedicated indicator light 238. The indicator lights 238 are positioned on the shelf 162. Each of the indicator lights 238 may include a plurality of light emitting diodes (LEDS). Each LED may be a different color. The indicator lights 238 are operable to indicate to a user the charging status of one of the battery packs 114, 118, 122 coupled to the ports 214, 230. For example, the indicator lights 238 may be green when a battery pack coupled to the port is fully charged. Alternatively, the indicator lights 238 may be red when a battery pack coupled to the port is being charged. Additionally, the indicator lights 238 may be a third color, different from red or green, to indicate something different to a user. For example, the indicator lights 238 may be yellow to indicate to a user of a fault in the connection between the port and the battery pack. Further, the indicator lights 238 may flash to indicate to a user another condition of the charging station 110. The indicator lights 238 are visible through openings 242 in the doors 138 when the doors 138 are in the closed configuration. The openings 242 allow a user to determine the status of a battery pack without needing to open the doors 138.

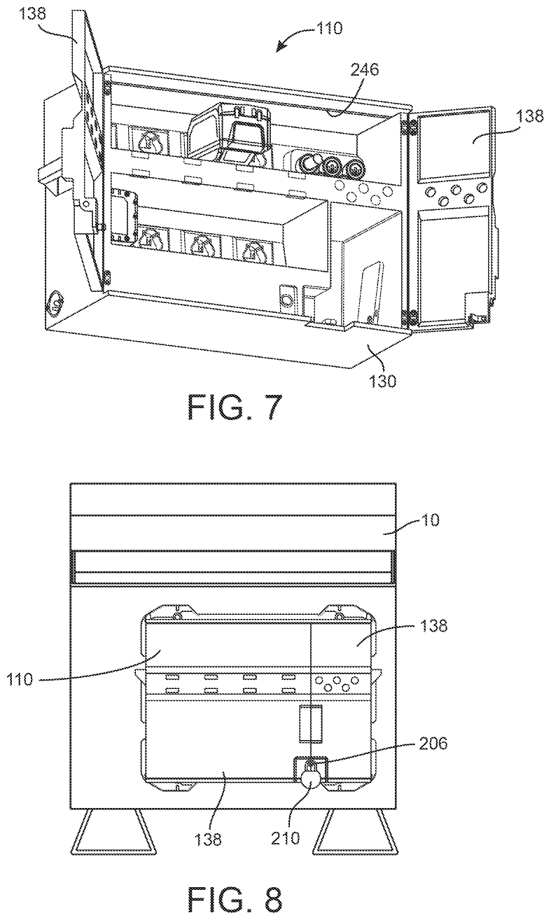

With reference to FIG. 7, a light strip 246 with a plurality of lights is disposed on a top surface of the housing 130. The light 246 is configured to illuminate the interior 134 of the housing 130 so a user can easily find components within the charging station 110. The light 246 may include a sensor that detects the ambient light in the environment around the charging station 110. For example, the sensor may determine that the ambient light is below a predetermined threshold and communicate to a controller to supply power to the light 246. Alternatively, the sensor may detect if the doors 138 are open and communicate to the controller to supply power to the light 246.

Although not shown, the charging station 110 may include a heating element. The heating element is configured to warm the battery packs stored within the interior 134 of the housing 130. Keeping the battery packs warm is critical, especially during cold weather, to ensure proper operation of the battery packs. In some embodiments, the heating element may be a conduction unit such as a heat blower. In other embodiments, the heating element may be an induction unit. In further embodiments, the charging station 110 may include insulation to reduce the amount of heat that escapes the interior 134 of the housing 130. A switch 250 on the interior 134 of the housing 130 may be selectively turned on to energize the heating unit.

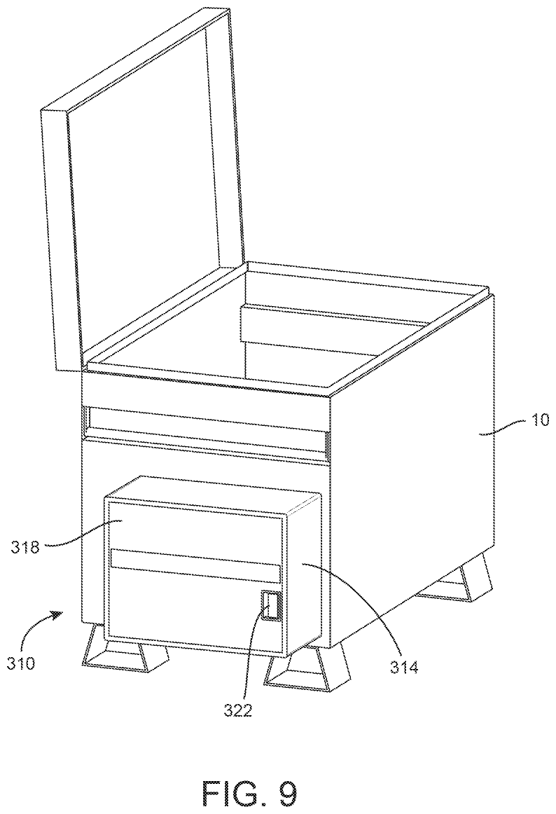

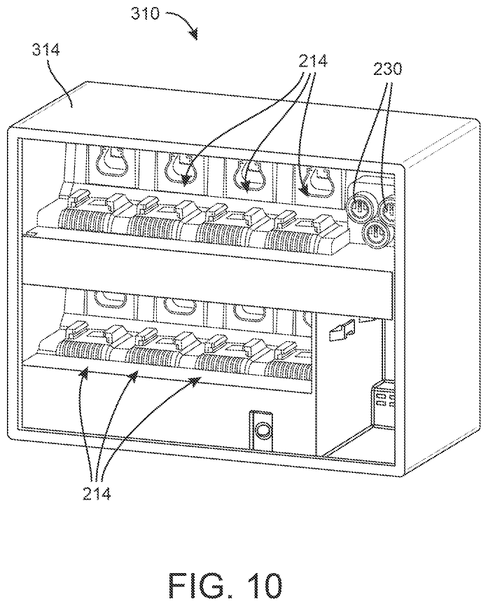

FIGS. 9 and 10 illustrate a charging station 310 for a gang box 10 according to another embodiment of the invention. The charging station 310 is similar to the charging station 110 with like features being represented with like reference numerals. The charging station 310 includes a housing 314 and a door 318 coupled to the housing 314 to selectively close the charging station 310. In the illustrated embodiment, the housing 314 is made of a metal material. Having a metal housing provides more durability and security to the charging station 310. The housing 314 may be directly coupled to the gang box 10 using fasteners. Similar to the charging station 110, the charging station 310 also includes a plurality of charging ports 214 and a plurality of secondary ports 230. The door 318 may be selectively opened with a handle 322. In some embodiments, the door 318 may be locked using a combination lock built into the door 318.

Providing a charging station that can be mounted to an exterior of a gang box advantageously provides more free space within the interior of the gang box.

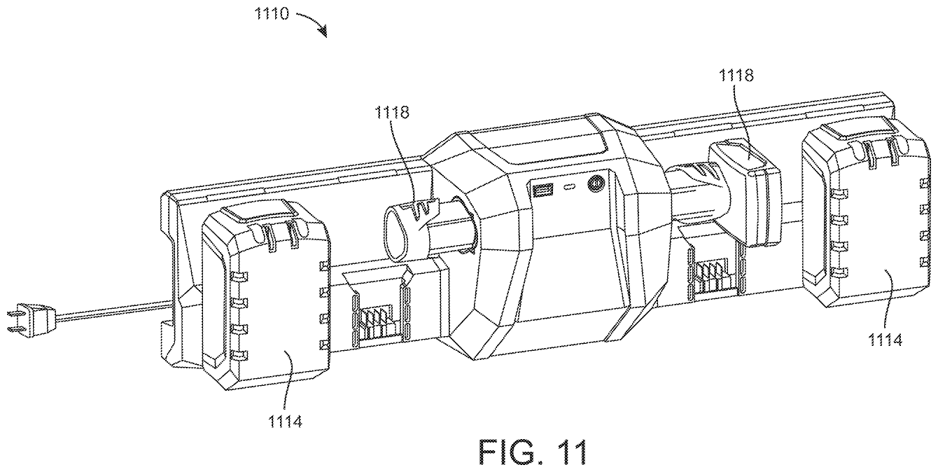

FIG. 11 illustrates a charging station 1110 according to one embodiment of the invention. The charging station 1110 is configured to couple or attach to a gang box 10 or job box that may be on a construction site or other worksite. Gang boxes typically hold tools and other equipment, such as power tools, that are necessary on the worksite. Power tools are operable to run off power provided by a battery or battery pack. During a workday, the battery packs deplete and need to be replaced with a fully charged battery pack. As such, the charging station 1110 provides power to battery packs that are coupled to the charging station 1110. In the illustrated embodiment, the charging station 1110 may support and charge a first battery pack 1114 or a second battery pack 1118 that is different from the first battery pack 1114. The battery packs 1114, 1118 may include any of several different nominal voltages (e.g., 12V, 18V, etc.), and may be configured having any number of different chemistries (e.g., lithium-ion, nickel-cadmium, etc.). The battery packs 1114, 1118 are removable coupled to the charging station 1110.

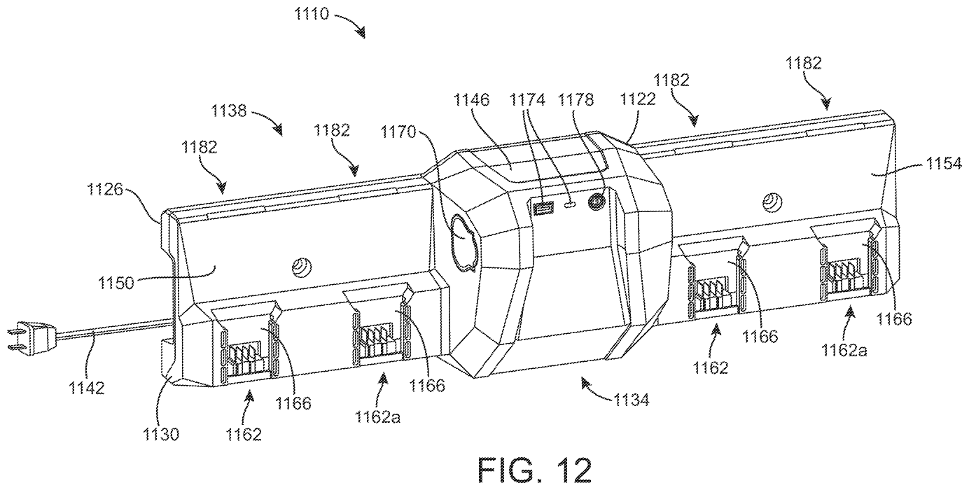

FIG. 12 illustrates the charging station 1110 without the battery packs 1114, 1118 removed. The charging station 1110 includes a housing 1122 that is formed of two clamshell pieces (i.e., a front housing 1126 and a back housing 1130). The housing 1122 defines a forward side 1134 and a rearward side 1138 opposite the forward side 1134. The housing 1122 defines a length L (FIG. 14) of the charging station 1110. In the illustrated embodiment, the length L of the charging station 1110 is approximately 24 inches for use with a gang box that is 48 inches. In some embodiments, the length L of the charging station 1110 is approximately half the length of the gang box to which it is coupled. In other embodiments, the length L of the charging station 1110 may be more than half the length or less than half the length of the gang box. As such, the gang box 10 may support a plurality of charging stations 1110 along its length. A power cord 1142 extends from the charging station 1110 to provide power to the charging station 1110. The power cord 1142 may be connected to a wall outlet supported by the gang box 10 or a wall outlet.

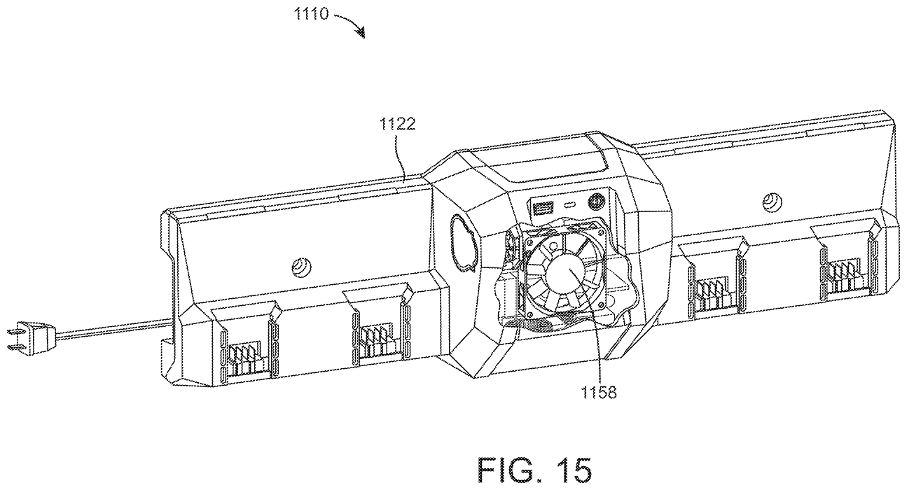

The housing 1122 includes an electronics hub 1146, a first wing 1150 extending from one side of the electronics hub 1146, and a second wing 1154 extending from the other side of the electronics hub 1146 opposite the first wing 1150. The electronics hub 1146 includes control electronics for the charging station 1110. The control electronics may include at least one controller or printed circuit board (PCB) that controls operation of the charging station 1110. As shown in FIG. 15, a fan 1158 is disposed within the housing 1122 to cool the control electronics. The fan 1158 may be operated by a motor (not shown).

With reference back to FIG. 12, the charging station 1110 includes a plurality of charging ports 1162. In the illustrated embodiment, the first wing 1150 includes two ports 1162 and the second wing 1154 includes two ports 1162. In other embodiments, the first and second wings 1150, 1154 may include less than two ports 1162 or more than two ports 1162. For example, the first wing 1150 may include one port 1162 and the second wing 1154 may include three or more ports 1162. Further, the charging station 1110 may not include the first wing 1150 and the second wing 1154 may include four ports 1162. Each of the ports 1162 defines at least one receptacle that is configured to receive a battery pack. The ports 1162 adjacent the electronics hub 1146 defines a horizontal port 1162a including a first battery receptacle 1166 positioned on a respective wing and a second battery receptacle 1170 that is different from the first battery receptacle 1166 positioned on the electronics hub 1146. The first battery receptacle 1166 forms a right angle with the second battery receptacle 1170. The ports 1162 that are not adjacent the electronics hub 1146 include the first battery receptacle 1166. The first battery receptacles 1166 are configured to receive the first battery pack 1114 and the second battery receptacles 1170 are configured to receive the second battery pack 1118. Each of the ports 1162 may include a dedicated controller to control the charging supplied to a battery pack 1114, 1118 that is coupled to the port 1162. In some embodiments, two of the ports 1162 charge simultaneously while two of the ports 1162 charge in sequential order. In other embodiments, all the ports 1162 may charge simultaneously or sequentially.

To state the above in another way, the electronics hub 1146 includes two of the second battery receptacles 1170 (i.e., one on each side of the electronics hub 1146), the first wing 1150 includes two of the first battery receptacles 1166, and the second wing 1154 includes two of the first battery receptacles 1166. The electronics hub 1146 may also include more than or less than two battery receptacles 1166, 1170. In the illustrated embodiment, the plurality of ports 1162 are positioned on a vertical plane. In other embodiments, the plurality of ports 1162 may be positioned on a horizontal plane facing either the top or bottom side of the housing 1122.

The electronics hub 1146 also includes a plurality of USB ports 1174 on a front side of the electronics hub 1146. The USB ports 1174 may be either USB-A or USB-C port. In other embodiments, the USB ports 1174 may be other USB types. The USB ports 1174 may be configured to charge phones, tablets, or the like through a charging cable. A power switch 1178 is also positioned on the electronics hub 1146. The power switch 1178 may be toggled by a user to supply power from a power outlet to charge the battery packs 1114, 1118 coupled to one of the plurality of ports 1162.

With continued reference to FIG. 12, each of the plurality of ports 1162 includes a dedicated indicator light 1182. Each of the indicator lights 1182 may include a plurality of light emitting diodes (LEDS). Each LED may be a different color. The indicator lights 1182 are operable to indicate to a user the charging status of one of the battery packs 1114, 1118 coupled to the ports 1162. For example, the indicator lights 1182 may be green when a battery pack coupled to the port 1162 is fully charged. Alternatively, the indicator lights 1182 may be red when a battery pack coupled to the port 1162 is being charged. Additionally, the indicator lights 1182 may be a third color, different from red or green, to indicate something different to a user. For example, the indicator lights 1182 may be yellow to indicate to a user of a fault in the connection between the port 1162 and the battery pack. Further, the indicator lights 1182 may flash to indicate to a user another condition of the charging station 1110. In the illustrated embodiment, each port 1162 may include a first indicator light 1182a on the forward side 1134 of the housing 1122 and a second indicator light 1182b on a top side of the housing 1122. Including an indicator light 1182 on both the forward and top sides of the housing 1122 allows a user to see the indicator lights 1182 from a plurality of positions around the gang box 10.

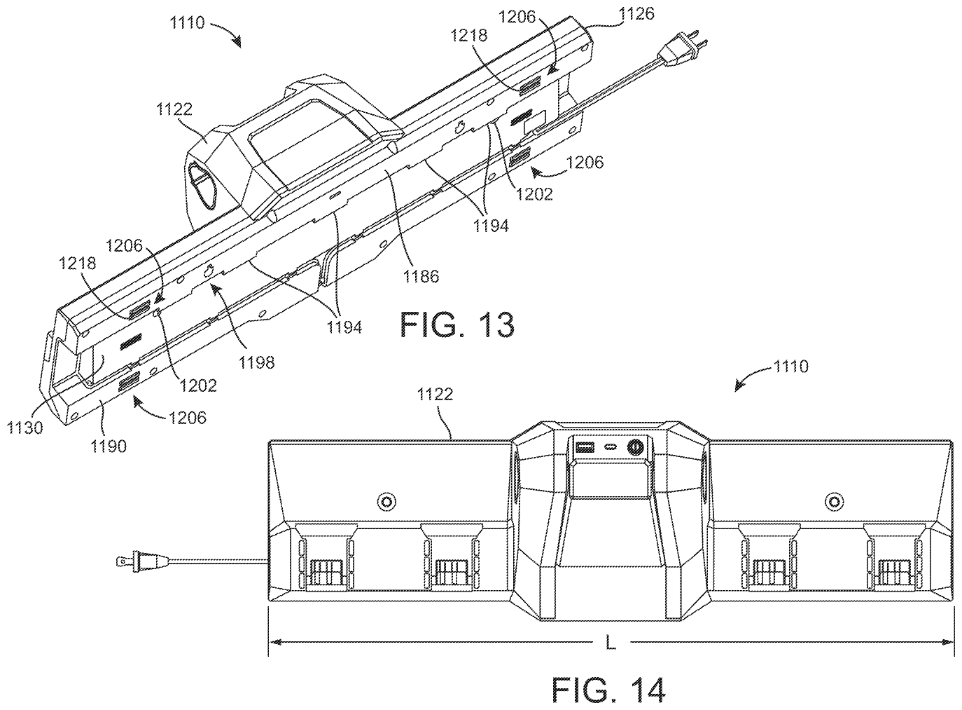

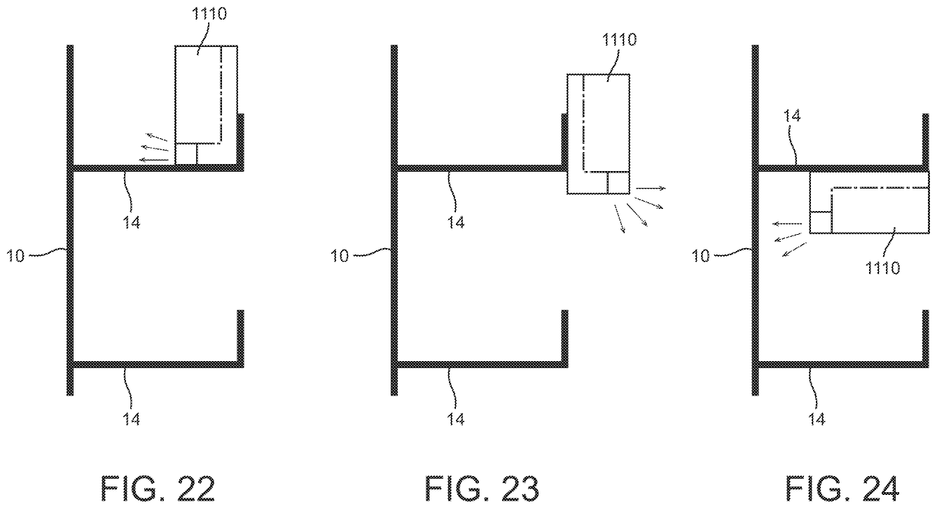

With reference to FIG. 13, the back housing 1130 includes a top rail 1186 and a bottom rail 1190. The top and bottom rails 1186, 1190 assist with attaching the charging station 1110 to the gang box 10 or other structure. The top rail 1186 includes a plurality of cleats 1194 that define a lip 1198. In other embodiments, the top rail 1186 may include a single cleat extending across the entire top rail 1186. A shelf 14 (FIG. 22) of a gang box 10 may be positioned within the lip 1198 to assist in supporting the charging station 1110 on a gang box 10. Alternatively, the lip 1198 may be coupled to a bracket on a wall or other structure to support the charging station 1110. In other embodiments, the charging station 1110 may include adjustable clips that allow a user to clip the charging station onto a shelf of the gang box 10. In further embodiments, the charging station 1110 may include a detachable cleat that allows a user to remove the cleat if the charging station 1110 is mounted to the gang box 10 or other structure in other ways. The back housing 1130 further includes a plurality of mounting apertures 1202 that extend through the housing 1122 between the forward and rearward sides 1134, 1138. The mounting apertures 1202 are configured to receive fasteners to assist in supporting the charging station 1110 from a gang box 10 or other structure.

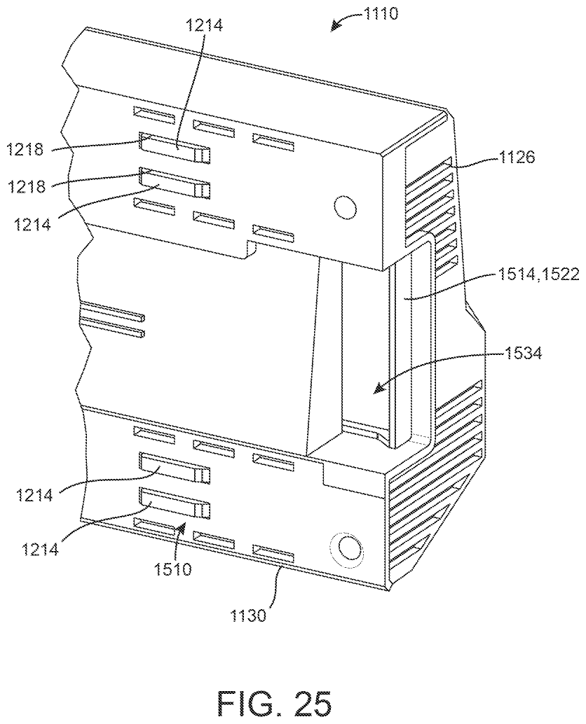

With continued reference to FIG. 13, the top and bottom rails 1186, 1190 also include a plurality of magnet assemblies 1206. Specifically, the top rail 1186 includes two magnet assemblies 1206 (one adjacent each corner of the back housing 1130) and the bottom rail 1190 includes two magnet assemblies 1206 (one adjacent each corner of the back housing 1130). In other embodiments, the top and bottom rails may include more than two magnet assemblies 1206 or less than two magnet assemblies 1206. As shown in FIG. 25, each magnet assembly 1206 includes at least one magnet 1210 and at least one billet 1214. The billets 1214 are made of a ferromagnetic material, such as metal or the like. The magnets 1210 produce a magnetic field within the billets 1214. The billets 1214 extend through openings 1218 in the back housing 1130 to couple the charging station 1110 to a surface of the gang box 10 or other mating surface to support the charging station 1110.

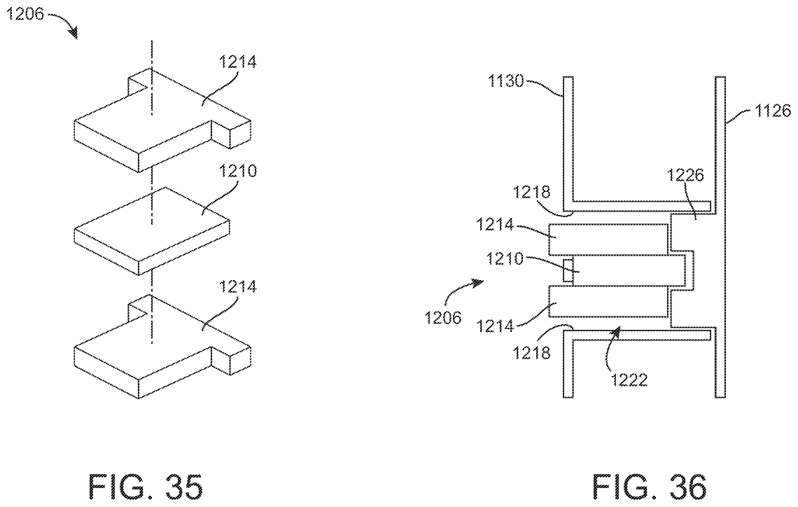

As shown in FIG. 35, the magnets 1210 are positioned between the two billets 1214 to produce the magnetic field. As shown in Fig, 36, the magnets 1210 and billets 1214 are positioned within pockets 1222 defined between the back housing 1130 and the front housing 1126. The pockets 1222 provide clearance between the magnet assembly 1206 and the housing 1122 to absorb the shock of engaging a mating surface. The clearance also allows the magnet assembly 1206 to adjust to the mating surface, for instance, if the mating surface is not smooth or includes dents. A back plate 1226 is positioned between the front and back housing 1126, 1130 to offset the magnets 1210 from the billets 1214 allowing the billets 1214 to extend from the openings 1218. In the illustrated embodiment, each magnet assembly 1206 requires at least 25 pounds of force to remove the magnet assembly 1206 from a mating surface. As such, the four magnet assemblies 1206 require at least a 100-pound force to remove the charging station 1110 from a mating surface. In other embodiments, each magnet 1210 may require between 25 and 60 pounds of force to remove the magnet assembly 1206 from the mating surface.

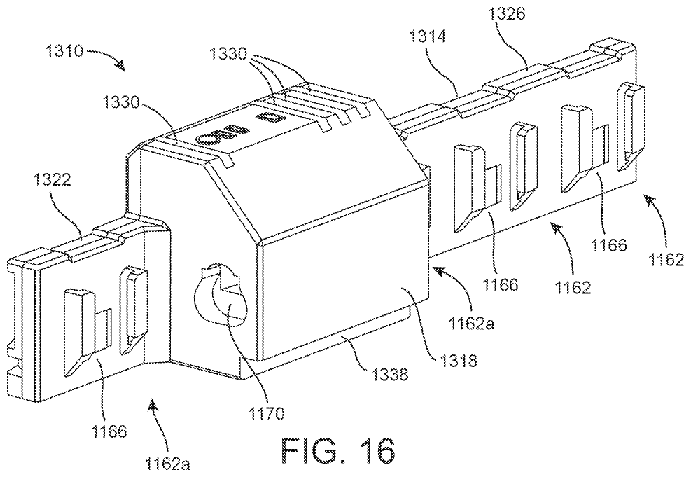

FIG. 16 illustrates a charging station 1310 according to another embodiment of the invention. The charging station 1310 is similar to the charging station 1110 with like features being represented with like reference numerals. The charging station 1310 includes a housing 1314 defining an electronics hub 1318, a first wing 1322 extending from one side of the electronics hub 1318, and a second wing 1326 extending from the opposite side of the electronics hub 1318. The charging station 1310 includes a plurality of ports 1162. A first horizontal port 1162a (i.e., a first battery receptacle 1166 and a second battery receptacle 1170) is defined between the first wing 1322 and the electronics hub 1318. A second horizontal port 1162a is defined between the second wing 1326 and the electronics hub 1318. The second wing 1326 also includes third and fourth ports 1162. In other words, the charging station 1110 includes one port 1162 on the first wing side of the electronics hub 1318 and three ports 1162 on the second wing side of the electronics hub 1318.

Similar to the charging station 1110, the charging station 1310 includes a dedicated indicator light 1330 for each of the ports 1162. The indicator lights 1330 extend from a top surface of the electronics hub 1318 to an inclined surface of the electronics hub 1318. Due to the indicator lights 1330 extending across multiple surfaces, the indicator lights 1330 are visible from multiple positions about the charging station 1310.

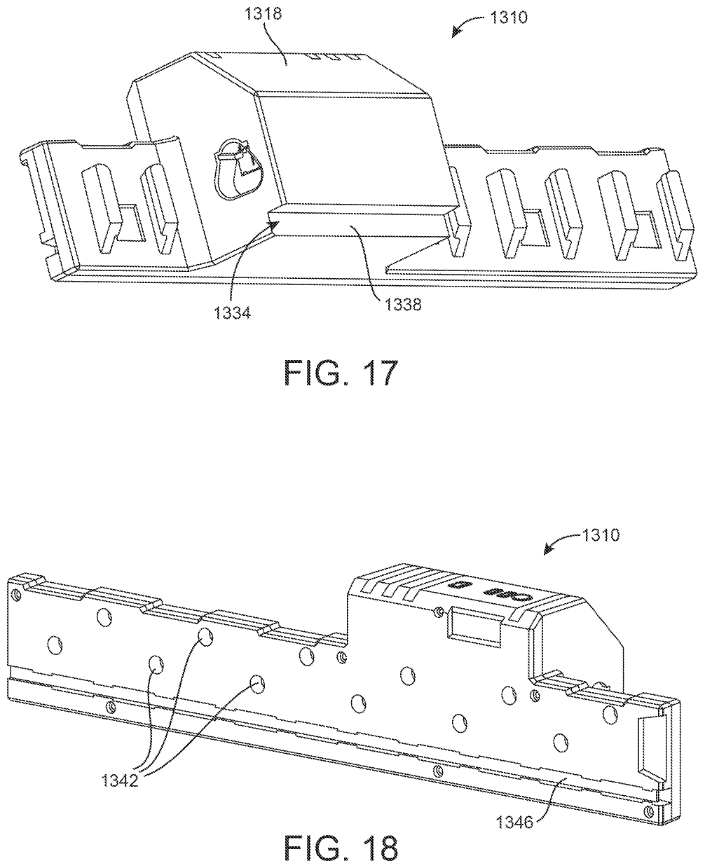

With reference to FIG. 17, the electronics hub 1318 defines a recess 1334 on a front side of the charging station 1310. A light 1338 may be positioned in the recess 1334 to illuminate an area in front of the charging station 1310. The light 1338 may include a sensor that detects the ambient light in the environment around the charging station 1310. For example, the sensor may determine that the ambient light is below a predetermined threshold and communicate to a controller to supply power to the light 1338. Alternatively, the sensor may detect if a lid or door of the gang box 10 is open and communicate to the controller to supply power to the light 1338. In some embodiments, the light 1338 may be removable coupled to the charging station 1310. As such, the light 1338 may be coupled to another position on the charging station 1310 to supply light to an area based on the user's needs.

Referring to FIG. 18, the charging station 1310 includes a plurality of mounting apertures 1342 configured to receive a fastener to facilitate supporting the charging station 1310 from a gang box 10 or other structure. The charging station 1310 further includes a power cord channel 1346. The power cord channel 1346 extends along the entire length of the charging station 1310. The power cord 1142 may extend within the channel 1346 to keep the power cord 1142 out of the way of power tools and other items within the gang box 10. In some embodiments, the power cord 1142 may be routed through the gang box 10 using magnetic clips that mate to a surface within the gang box 10. In further embodiments, the charging station 1310 may include a cord wrap that the power cord 1142 may be wrapped around to reduce the amount of slack provided to the power cord 1142.

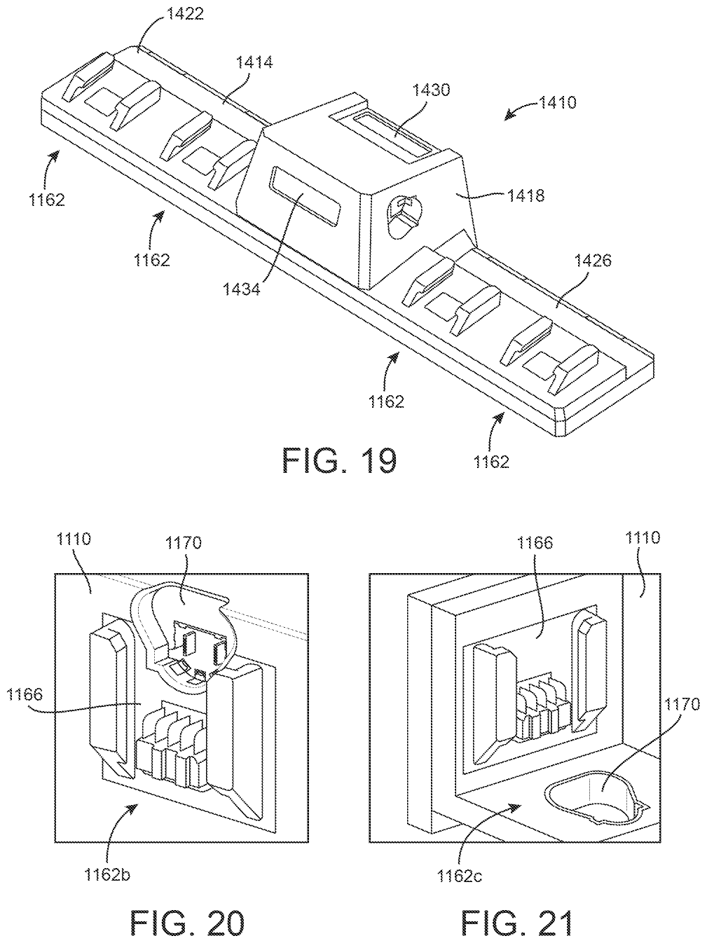

FIG. 19 illustrates a charging station 1410 according to another embodiment of the invention. The charging station 1410 is similar to the charging station 1110 with like features being represented with like reference numerals. The charging station 1410 includes a housing 1414 defining an electronics hub 1418, a first wing 1422 extending from one side of the electronics hub 1418, and a second wing 1426 extending from a second side of the electronics hub 1418 opposite the first wing 1422. The charging station 1410 also includes a plurality of ports 1162 configured to receive and charge the battery packs 1114, 1118. The electronics hub 1418 includes a first light 1430 facing a first direction and a second light 1434 facing a second direction. When the first and second lights 1430, 1434 are powered, an area in front of the charging station 1410 and an area below the charging station 1410 are illuminated.

FIG. 20 illustrates a port 1162b according to another embodiment of the invention for use with the charging station 1110. The port 1162b is a nested port and includes a second battery receptacle 1170 imbedded in a first battery receptacle 1166. As such, both the first and second battery packs 1114, 1118 may be alternatively coupled to the port 1162b for charging. The nested port 1162b is interchangeable with any of the ports 1162 defined on the charging station 1110.

FIG. 21 illustrates a port 1162c according to another embodiment of the invention for use with the charging station 1110. The port 1162c is a vertical port and includes a first battery receptacle 1166 positioned on either the first or second wing 1150, 1154 and a second battery receptacle 1170 that is at a right angle to the first battery receptacle 1166. The vertical port 1162c is interchangeable with any of the ports 1162 defined on the charging station 1110.

FIG. 22-24 illustrate different mounting positions for the charging station 1110 on a gang box 10. FIG. 22 illustrates the charging station 1110 supported on top of a shelf 14 of the gang box 10. FIG. 23 illustrates the charging station 1110 on a side of the shelf 14 of the gang box 10. The charging station 1110 may be coupled to the side of the shelf 14 using the cleats 1194, the magnet assemblies 1206, or both the cleats 1194 and the magnet assemblies 1206. In other embodiments, the charging station 1110 may be attached to the shelf 14 in other ways. FIG. 24 illustrates the charging station 1110 attached to the bottom of the shelf 14 of the gang box 10. The charging station 1110 may be coupled to the bottom of the shelf 14 using the magnet assemblies 1206. In other embodiments, the charging station 1110 may be coupled to the bottom of the shelf 14 in other ways.

FIG. 25 illustrates a magnet assembly 1510 according to another embodiment for use with the charging station 1110. The magnet assembly 1510 is positioned between the front and back housing 1126, 1130. In the illustrated embodiment, the magnet assembly 1510 is slidable in a linear direction parallel to the length L of the charging station 1110. The magnet assembly 1510 includes a handle 1514, a plurality of magnets 1210, and a plurality of billets 1214. The handle 1514 defines a grip portion 1522, a first cavity 1526 adjacent the top of the housing 1122 and a second cavity 1530 adjacent the bottom of the housing 1122. The grip portion 1522 extends into an opening 1534 between the front and back housing 1126, 1130 that is accessible to a user. In the illustrated embodiment, each cavity 1526, 1530 includes two magnets 1210 positioned between two billets 1214.

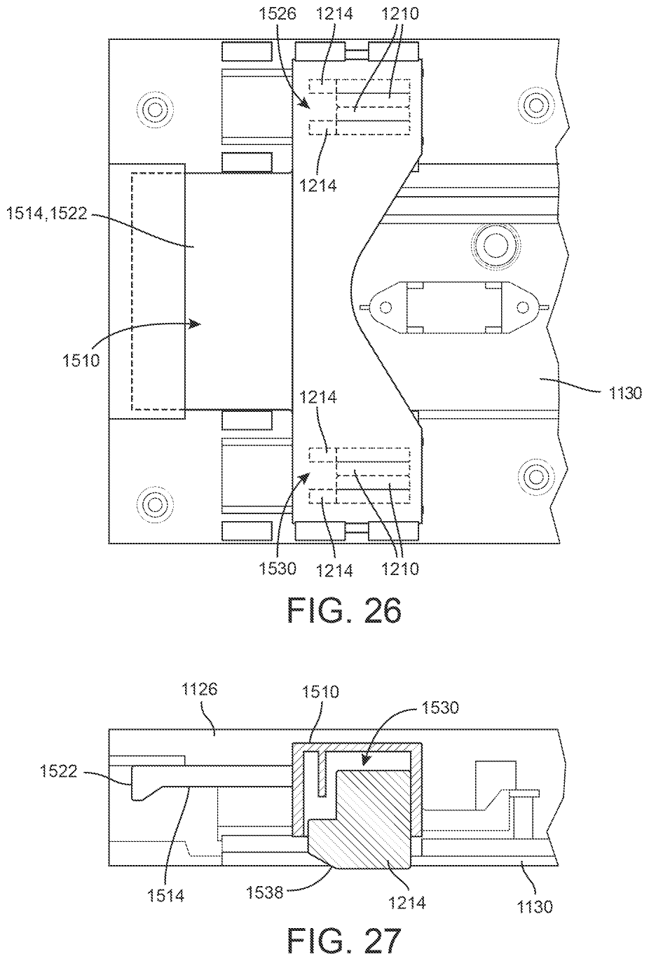

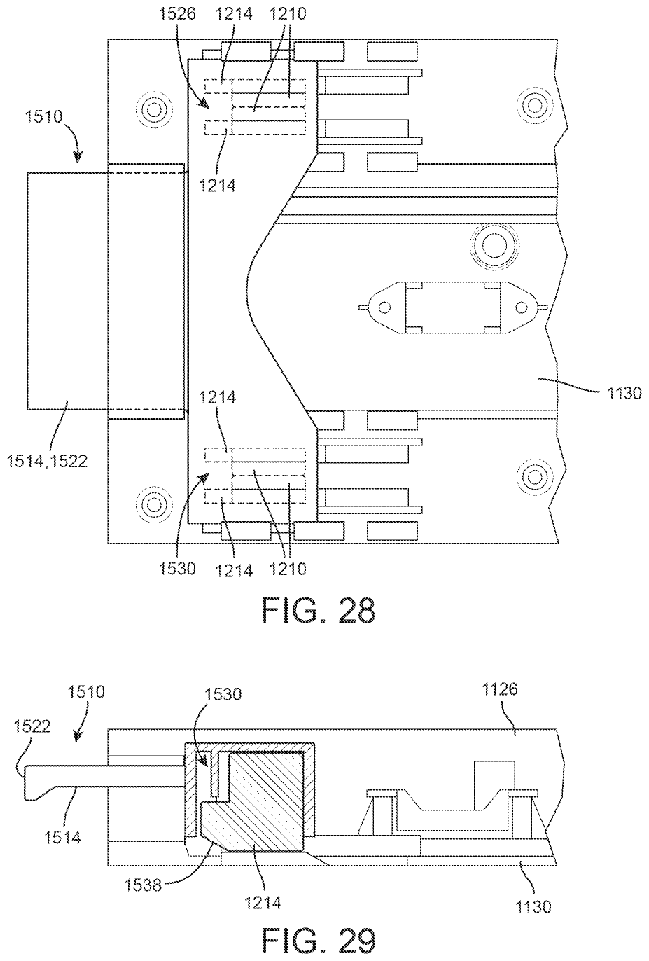

As shown in FIG. 27, the billets 1214 include an inclined surface 1538 that mates with a ramp 1542 of the housing 1122. The magnet assembly 1510 is moveable between a first position (FIGS. 26 and 27) and a second position (FIGS. 28 and 29) to remove the charging station 1110 from a mating surface of the gang box 10. A user may grab the grip portion 1522 and pull the handle 1514 away from the housing 1122. As a user pulls the handle 1514 away from the housing 1122, the inclined surfaces 1538 engage the ramp 1542 and begin to pull the billets 1214 and magnets 1210 away from the mating surface of the gang box 10. As the billets 1214 and magnets 1210 are pulled away from the mating surface, the attraction between the magnet assembly 1510 and the mating surface weaken. When the handle 1514 is the second position, the billets 1214 and magnets 1210 are completely decoupled from the mating surface allowing the user to remove the charging station 1110 from the surface.

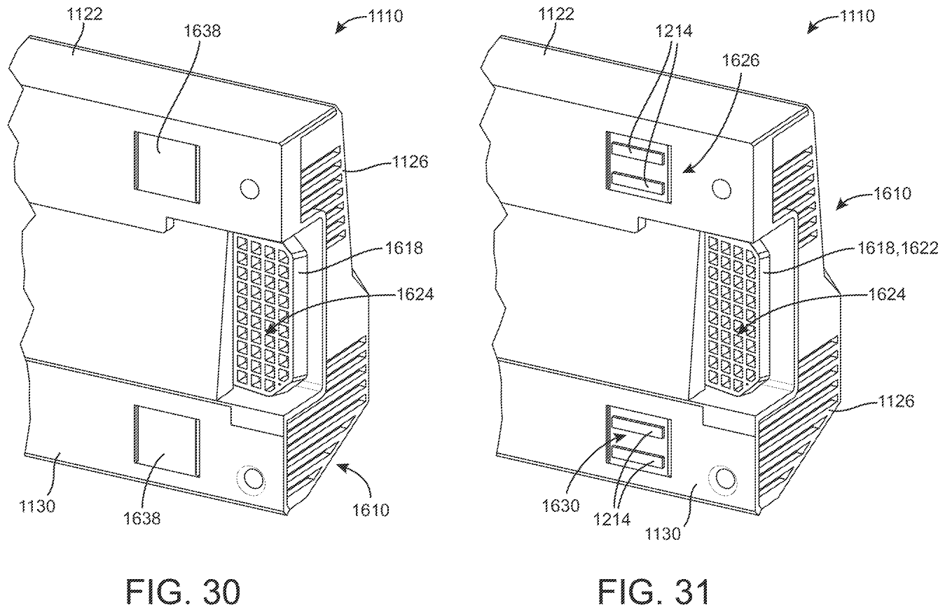

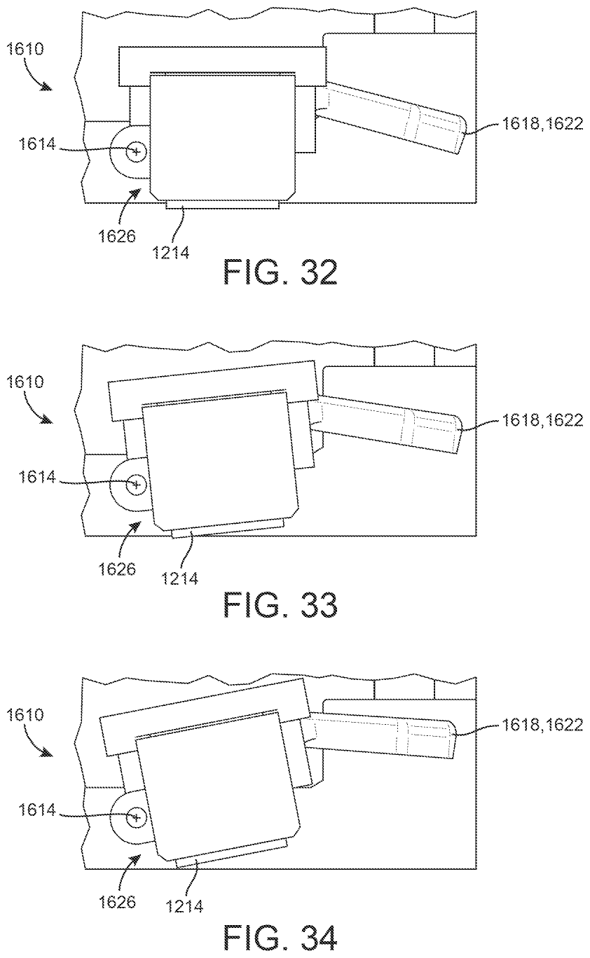

FIGS. 30 and 31 illustrate a magnet assembly 1610 according to another embodiment for use with the charging station 1110. The magnet assembly 1610 is similar to the magnet assembly 1510 discussed above with like features being represented by like reference numerals. The magnet assembly 1610 is positioned between the front and back housings 1126, 1130. In the illustrated embodiment, the magnet assembly 1610 is pivotable about a pivot point 1614 (FIG. 32). The magnet assembly 1610 includes a handle 1618, a plurality of magnets 1210, and a plurality of billets 1214. The handle 1618 defines a grip portion 1622, a first cavity 1626 adjacent the top of the housing 1122 and a second cavity 1630 adjacent the bottom of the housing 1122. The grip portion 1622 extends into an opening 1624 between the front and back housings 1126, 1130 that is accessible by a user. In the illustrated embodiment, each cavity 1626, 1630 includes at least one magnet 1210 positioned between two billets 1214. A cover 1638 is provided over the cavities 1626, 1630 to protect the ingress of dust, water, etc. from entering the cavities 1626, 1630.

With reference to FIGS. 32-34, the magnet assembly 1610 is moveable between a first position (FIG. 32) and a second position (FIG. 34) to remove the charging station 1110 from a surface of the gang box 10 or other mating surface. A user may grab the grip portion 1622 to pull the handle 1618 away from the mating surface, pivoting the magnet assembly 1610 about the pivot point 1614. In other words, the handle 1618 acts a lever finger to disengage the magnets 1210 and the billets 1214 from the mating surface. As the handle 1618 is moved away from the mating surface, the billets 1214 begin to uncouple from the mating surface (FIG. 33). When the magnet assembly 1610 is in the second position, the billets 1214 are completely decoupled from the mating surface allowing the user to remove the charging station 1110 from the mating surface.

In other embodiments, the charging station 1110 may include a magnet assembly with a rotatable handle with magnets coupled to the handle. The handle may rotate to move the magnets away from the mating surface lowering the force required to remove the charging station 1110 from the mating surface.

Providing a charging station with multiple ports that can couple to a gang box supplies a central location for multiple batteries to be charged and stored. A user can swap between battery packs whenever the current battery pack is low on power. Also, providing a charging station with a magnet assembly that couples and decouples the charging station to a mating surface allows a user toolless attachment and detachment from a gang box. Further, providing a charging station with an electronics hubs and wings allows for the charging station to occupy minimal space within the gang box.

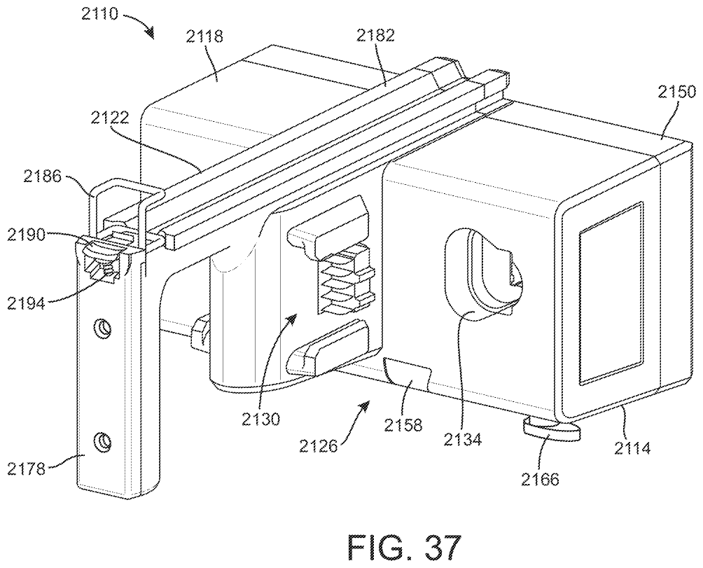

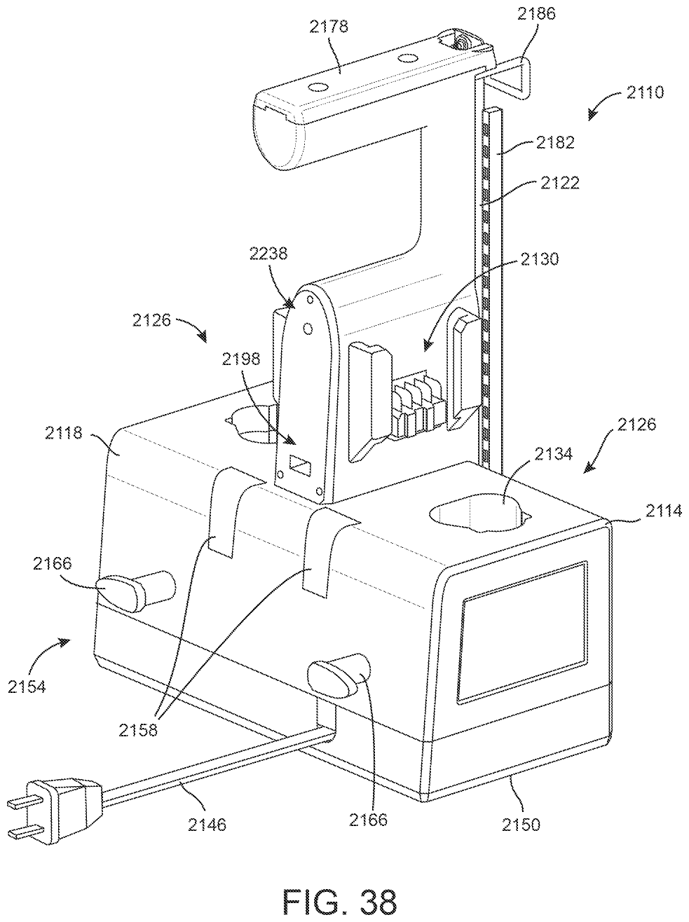

FIGS. 37 and 38 illustrate a charging station 2110 according to another embodiment of the invention. The charging station 2110 is configured to receive and charge multiple battery packs externally from a gang box 10. As such, the charging station 2110 is a portable charging station that can be transported to a specific jobsite location to charge additional battery packs without the need to return to the gang box 10 for a new battery pack.

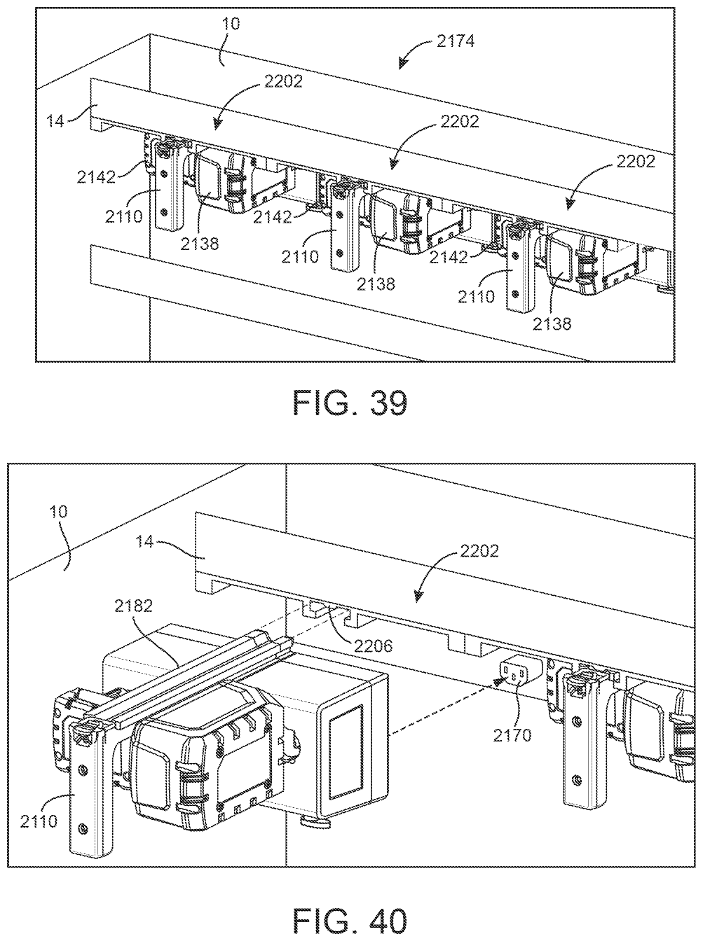

The charging station 2110 includes a housing 2114 that defines a power block 2118 and a handle 2122 extending from the power block 2118. A plurality of charging ports 2126 are defined between the power block 2118 and the handle 2122. In the illustrated embodiment, the charging station 2110 includes a first charging port 2126 on a first side of the handle 2122 and a second charging port 2126 on a second side of the handle 2122 opposite the first side. In other embodiments, the charging station 2110 may include more than two charging ports 2126 disposed on the housing 2114. Each of the charging ports 2126 includes a first battery receptacle 2130 that is disposed on the handle 2122 and a second battery receptacle 2134 that is different from the first battery receptacle 2130 disposed on the power block 2118. The first battery receptacle 2130 is configured to receive and charge a first battery pack 2138 and the second battery receptacle 2134 is configured to receive and charge a second battery pack 2142 that is different from the first battery pack 2138 (FIG. 39). In other embodiments, the charging ports 2126 may only include one battery receptacle. In the illustrated embodiment, the first battery receptacle 2130 is orientated at a right angle relative to the second battery receptacle 2134.

The power block 2118 includes an interior that houses the control electronics for the charging station 2110. The control electronics may include at least one controller or printed circuit board (PCB) that controls operation of the charging station 2110. In some embodiments, each of the charging ports 2126 may include a dedicated PCB that individually controls charging to the ports 2126. A power cord 2146 extends from the power block 2118 to supply power to the charging station 2110 and the battery packs 2138, 2142 coupled to the charging station 2110. The power cord 2146 can be coupled to a power outlet to transfer power to the charging station 2110. Additionally, the charging station 2110 is a dedicated charger. In other words, the charging station 2110 is capable of charging the battery packs 2138, 2142 when the charging station 2110 is not coupled to a power outlet.

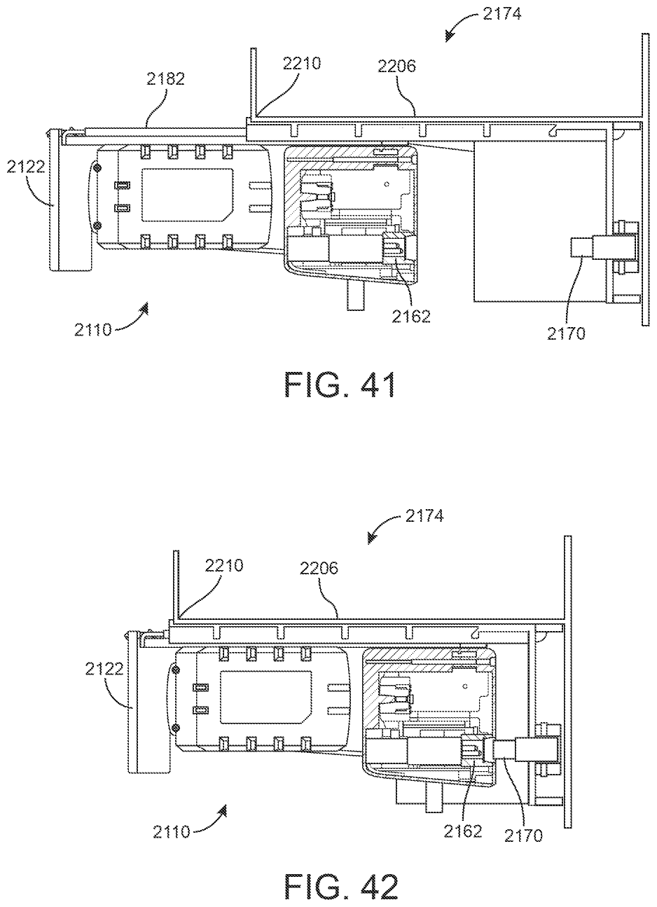

The power block 2118 defines a base 2150 that supports the charging station 2110 on a surface in a vertical orientation. In other words, when the base 2150 is supported on a surface, the handle 2122 is vertically oriented. The power block 2118 also includes a cord wrap 2154, indicator lights 2158, and a male power terminal 2162 (FIG. 41). The cord wrap 2154 includes two projections 2166 that the power cord 2146 can be wrapped around to store the power cord 2146 when not in use.

In the illustrated embodiments, each charging port 2126 includes a dedicated indicator light 2158. Each of the indicator lights 2158 may include a plurality of light emitting diodes (LEDS). Each LED may be a different color. The indicator lights 2158 are operable to indicate to a user the charging status of one of the battery packs 2138, 2142 coupled to the charging ports 2126. For example, the indicator lights 2158 may be green when a battery pack coupled to the charging port 2126 is fully charged. Alternatively, the indicator lights 2158 may be red when a battery pack coupled to the charging port 2126 is being charged. Additionally, the indicator lights 2158 may be a third color, different from red or green, to indicate something different to a user. For example, the indicator lights 2158 may be yellow to indicate to a user of a fault in the connection between the charging port 2126 and the respective battery pack 2138, 2142. Further, the indicator lights 2158 may flash to indicate to a user another condition of the charging station 2110. The indicator lights 2158 extend over multiple surfaces of the power block 2118 allowing the indicator lights 2158 to be viewable by a user from multiple orientations. The male power terminal 2162 is operable to connect to a female terminal 2170 (FIG. 40) of a docking station 2174 to transfer power to the charging station 2110 as will be discussed in more detail below.

The handle 2122 includes a grip portion 2178 and a rail 2182 extending from the grip portion 2178 to the power block 2118. The grip portion 2178 allows a user to grasp the charging station 2110 to facilitate transporting the charging station 2110. The grip portion 2178 includes an extendable hook 2186 and a locking trigger 2190. The extendable hook 2186 may be extended away from the handle 2122 to support the charging station 2110 from a structure. For example, the hook 2186 may attach to the lip of a shelf or cart. The locking trigger 2190 is pivotable relative to the grip portion 2178 between a locked and unlocked position. A biasing member 2194 (e.g., a spring) biases the locking trigger 2190 to the locked position. The handle 2122 also includes a USB port 2198. The USB port 2198 may be either a USB-A or USB-C port. In other embodiments, the USB port 2198 may be other USB types. The USB port 2198 may be configured to charge phones, tablets, or the like through a charging cable. In the illustrated embodiment, the charging station 2110 includes a single USB port 2198. In other embodiments, the charging station 2110 may include more than one USB port 2198.

FIGS. 39 and 40 illustrate a docking station 2174 that is operable to support and charge the charging station 2110. The docking station 2174 may be coupled to a gang box 10. For example, the docking station 2174 may be coupled to the underside of a shelf 14 of the gang box 10. The docking station 2174 includes a plurality of docks 2202 to receive multiple charging stations 2110. In the illustrated embodiment, the docking station 2174 includes three docks 2202 to receive three charging stations 2110. In other embodiments, the docking station 2174 may include more than or less than three docks 2202. Each dock 2202 includes a female terminal 2170 and a track 2206. The female terminal 2170 is operable to couple to the male power terminal 2162 of the charging station 2110 to transfer power to the charging station 2110. The track 2206 is operable to receive the rail 2182 of the handle 2122 to support the charging station 2110 in the dock 2202.

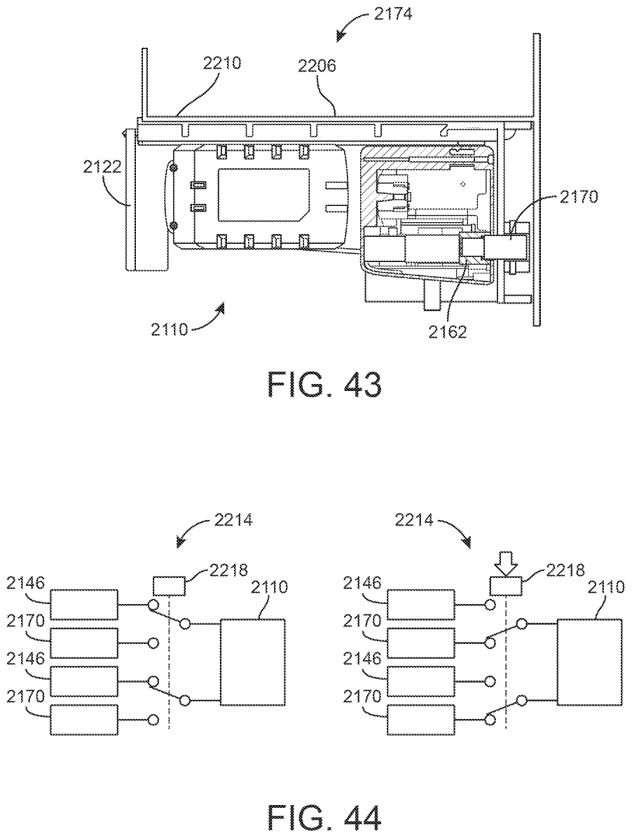

With reference to FIGS. 41-43, when the charging station 2110 needs to be recharged or stored, a user can return the charging station 2110 to the docking station 2174. To place the charging station 2110 in the docking station 2174, a user aligns the rail 2182 of the handle 2122 of the charging station 2110 with the track 2206 of an open dock 2202 (FIG. 41). Once the track 2206 receives the rail 2182, a user can slide the charging station 2110 along the track 2206 towards the back of the dock 2202 until the male power terminal 2162 couples to the female terminal 2170 (FIG. 43). Simultaneously, a lip 2210 on the end of track 2206 engages the locking trigger 2190 to pivot the locking trigger 2190 against the bias of the biasing member 2194. Once the locking trigger 2190 passes the lip 2210, the locking trigger 2190 returns to the locked position to secure the charging station 2110 to the dock 2202. Once the charging station 2110 is fully inserted into the dock 2202, power is transferred to the charging station 2110. A user can remove the charging station 2110 from the dock 2202 by pivoting the locking trigger 2190 against the bias of the biasing member 2194 out of the path of the lip 2210 and sliding the charging station 2110 away from the dock 2202.

With reference to FIG. 44, the charging station 2110 includes a circuit 2214 to prevent the power cord 2146 from holding a charge when the charging station 2110 is coupled to the dock 2202. The circuit 2214 includes a switch 2218 that changes the passage of electricity to the charging station 2110. Once the male power terminal 2162 is coupled to the female terminal 2170, the switch 2218 changes the passage of electricity to the charging station 2110 from the power cord 2146 to the female terminal 2170.

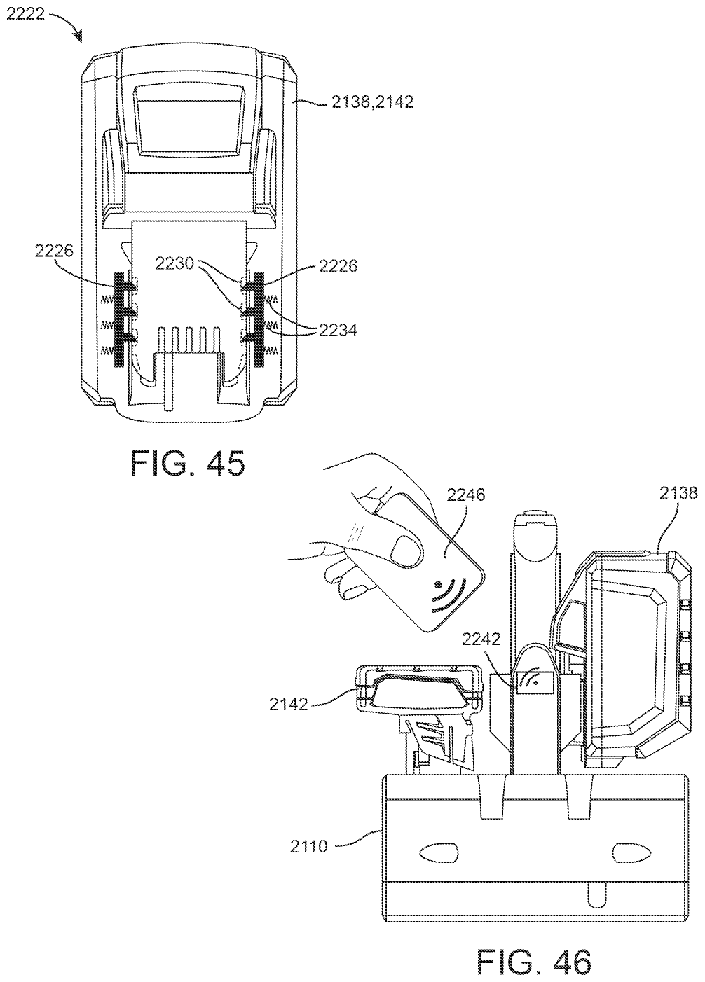

FIG. 45 illustrates a battery locking mechanism 2222 for use with the charging station 2110. The battery locking mechanism 2222 may lock the battery packs 2138, 2142 in one of the battery receptacles 2130, 2134. The battery locking mechanism 2222 includes an actuator 2226 (e.g., cleats) that engage with recesses 2230 on the battery packs 2138, 2142. Upon insertion of a battery pack 2138, 2142 to the battery receptacle 2130, 2134, the actuator 2226 engages the recesses 2230 preventing the battery pack 2138, 2142 from being removed from the battery receptacle 2130, 2134. The actuator 2226 may be activated by solenoids 2234 that move the actuator 2226 to engage the battery pack 2138, 2142. A security indicator light 2238 (FIG. 38) on the handle 2122 may indicate to a user that the battery pack 2138, 2142 is locked in the battery receptacle 2130, 2134.

With reference to FIG. 46, to remove the battery pack 2138, 2142, the charging station 2110 may include an electronic reader 2242 (e.g., RFID, NFC, Bluetooth, etc.) that communicates to the solenoids 2234 to release the battery pack 2138, 2142. For example, a user may scan an ID badge 2246 to the electronic reader 2242 signaling the solenoids 2234 to release the battery pack 2138, 2142. Alternatively, a user may communicate via Bluetooth to the electronic reader 2242 using a phone or remote to release the battery pack 2138, 2142. In other embodiments, the actuator 2226 of the battery locking mechanism 2222 may include a hook or a bollard that pivots to lock the battery pack 2138, 2142 in the battery receptacle 2130, 2134 instead of the cleats. Providing a battery locking mechanism prevents unwanted removal of the battery packs from the battery receptacle.

Providing a portable charging station allows a user to carry multiple battery packs to specific locations without needing to return to a central location to exchange the battery packs.

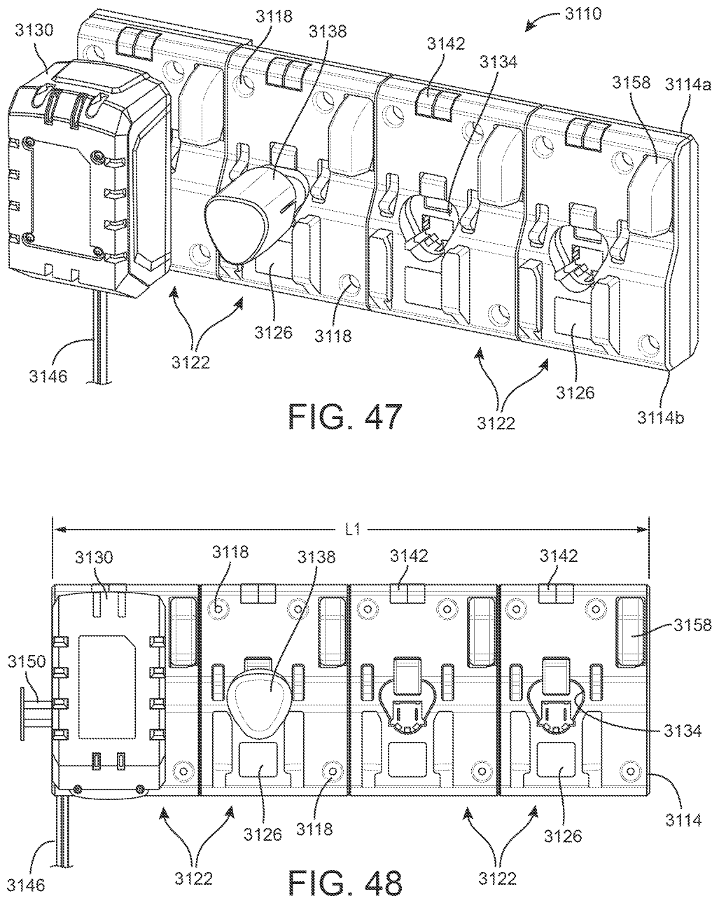

FIGS. 47 and 48 illustrate a charging station 3110 according to another embodiment of the invention. The charging station 3110 is configured to couple to a gang box 10. Preferably, the charging station 3110 is coupled to an interior surface of the gang box 10. The charging station 3110 receives power from an external source to charge battery packs coupled to the charging station 3110.

The charging station 3110 includes a housing 3114 having a back housing 3114a and a front housing 3114b. The housing 3114 defines a length L1 of the charging station 3110. In the illustrated embodiment, the length L1 of the charging station 3110 is approximately 24 inches for use with a gang box that is 48 inches. In some embodiments, the length L of the charging station 3110 is approximately half the length of the gang box to which it is coupled. In other embodiments, the length L1 of the charging station 3110 may be more than half the length or less than half the length of the gang box. As such, the gang box 10 may support a plurality of charging stations 3110 along its length. The housing 3114 also defines a low profile. In other words, the width of the housing 3114 is minimalized. The housing 3114 includes a plurality of mounting apertures 3118 that are configured to receive fasteners to couple the charging station 3114 to a gang box 10 or other structure.

The housing 3114 defines a plurality of charging ports 3122. The charging ports 3122 are all aligned linearly along the length L1 of the housing 3114. In the illustrated embodiment, the charging station 3110 includes four charging ports 3122. In other embodiments, the charging station 3110 may include more than or less than three charging ports 3122. Each charging port 3122 includes a first battery receptacle 3126 to receive and charge a first battery pack 3130 and a second battery receptacle 3134 that is different from the first battery receptacle 3126 to receive and charge a second battery pack 3138. As such, the first or second battery packs 3130, 3138 may be alternatively coupled to one of the charging ports 3122.

In the illustrated embodiment, the second battery receptacle 3134 is nested in the first battery receptacle 3126. In other words, the first and second battery receptacles 3126, 3134 are within the same plane. In other embodiments, the charging ports 3122 may only include either the first or second battery receptacles 3126, 3134. In further embodiments, the charging ports 3122 may be modular. In other words, each charging port 3122 may be selectively coupled to another charging port 3122 to customize the charging station 3110 to a user' preference. Further, other charging ports that are different from the charging ports 3122 may be coupled to the charging station 3110 to charge another device or battery pack (e.g., radios, lights, etc.). In alternative embodiments, a storage pocket may be coupled to the charging station 3110 in lieu of a charging port 3122 to store cords, devices, or the like. Each charging port 3122 also includes a dedicated indicator light 3142 similar to the indicator lights 2158, 1182, 238 described above. A power cord 3146 is coupled to the charging station 3110 to supply power from an external device to the charging ports 3122 to charge the battery packs 3130, 3138. The power cord 3146 may be decoupled from the charging station 3110 and coupled to another external device or charging station 3110 to supply power to the device. The power cord 3146 may be stored on a cord wrap 3150 attached to the housing 3114 of the charging station 3110.

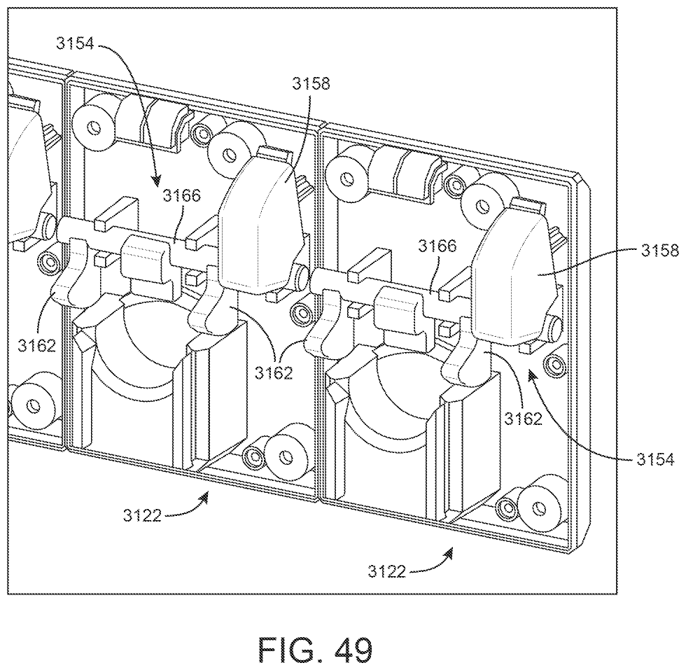

With reference to FIG. 49, each charging port 3122 includes an ejection mechanism 3154 to eject a battery pack 3130, 3138 from a battery receptacle 3126, 3134. The ejection mechanism 3154 includes a button 3158 that extends from the housing 3114, two cam lobes 3162, and a rod 3166 connecting the button 3158 to the cam lobes 3162. To eject a battery pack 3130, 3138 from a battery receptacle 3126, 3134, a user can depress the button 3158 into the housing 3114. Depressing the button 3158 pivots the rod 3166, which in turn rotates the cam lobes 3162. The cam lobes 3162 engage the battery pack 3130, 3138 to push the battery pack 3130, 3138 out of the respective battery receptacle 3126, 3134. The ejection mechanism 3154 allows for a user to eject a battery pack 3130, 3138 using a single hand.

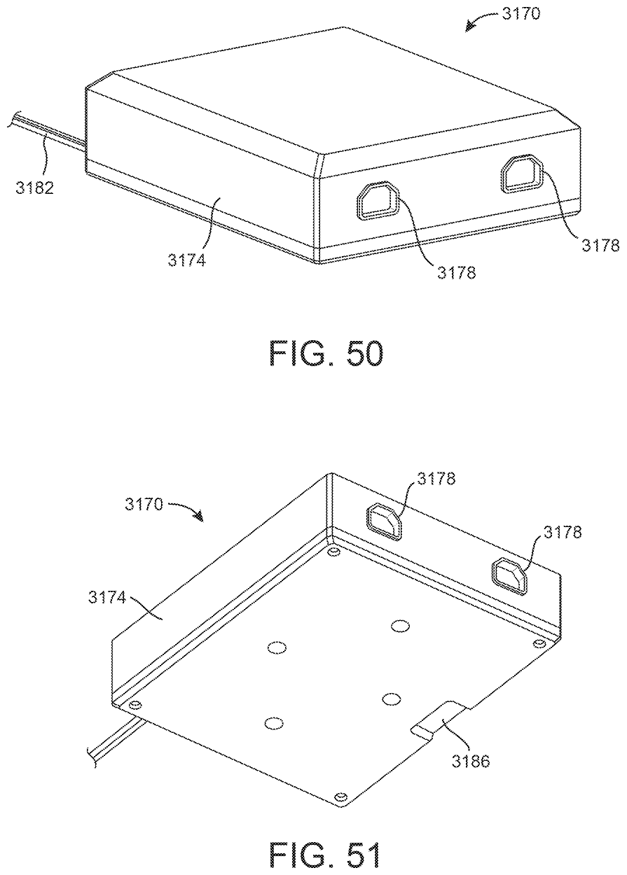

FIGS. 50 and 51 illustrate a power hub 3170 that supplies power to the charging station 3110. The power hub 3170 includes a housing 3174, a plurality of power outlets 3178, and power cord 3182. The housing 3174 is generally cube-shaped or brick-shaped. The housing 3174 includes control electronics for the charging station 3110. The control electronics may include at least one controller or printed circuit board (PCB) that controls operation of the charging station 3110. The power outlets 3178 are operable to receive the power cord 3146 of the charging station 3110 to transfer power from the power hub 3170 to the charging station 3110. Each power outlet 3178 is capable of providing power from the power hub 3170 to an external device. As such, multiple charging stations 3110 can be coupled to the power hub 3170 to receive power from the power hub 3170. The power cord 3182 is an A/C plug that may be plugged into a wall outlet.

The power hub 3170, charging station 3110, and the power cord 3146 are part of a charging assembly. The power hub 3170 allows for the electronics of the charging station 3110 to be separate from the charging station 3110 allowing the housing 3114 of the charging station 3114 to have a minimal profile. In some embodiments, both the housing 3174 of the power hub 3170 and the housing 3114 of the charging station 3110 may include one or more magnet assemblies similar to the magnet assemblies 1206 discussed above. The magnet assemblies may couple the power hub 3170 and the charging station 3110 to a mating surface. For example, the power hub 3170 may be positioned on an external surface of a gang box 10 while the charging station 3110 may be disposed on an internal surface of the gang box 10. The power cord 3146 may then be routed through the gang box 10 to supply power from the power hub 3170 to the charging station 3110. Positioning the power hub 3170 external to the gang box 10 frees up space within the gang box 10 for other devices such as power tools or the like. The housing 3174 of the power hub 3170 defines a recess 3186 to assist in removing the power hub 3170 from a mating surface. For example, a lever may be positioned in the recess 3186 to separate the magnet assemblies 1206 from the mating surface to remove the power hub 3170.

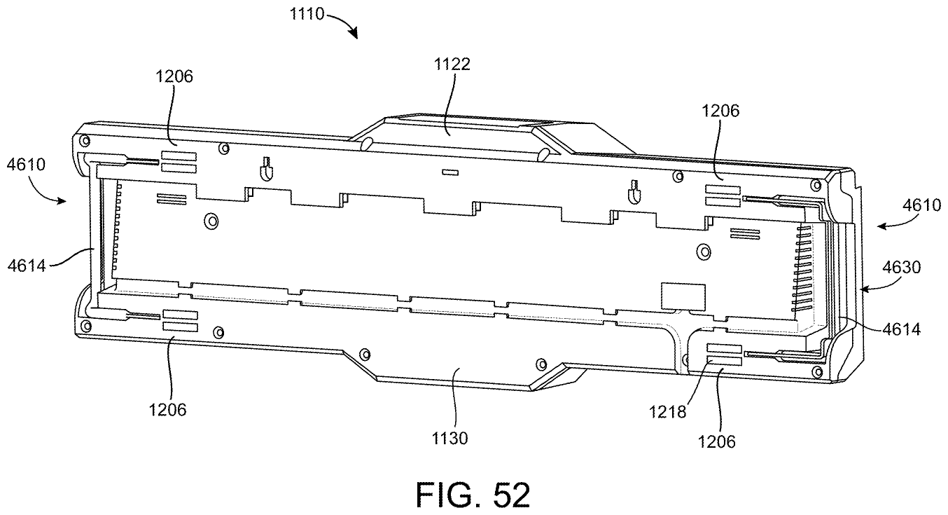

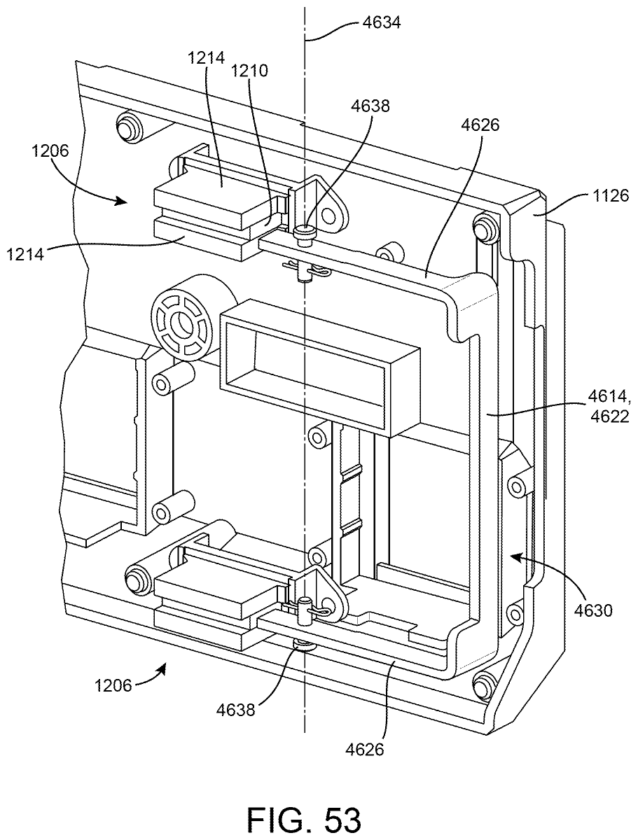

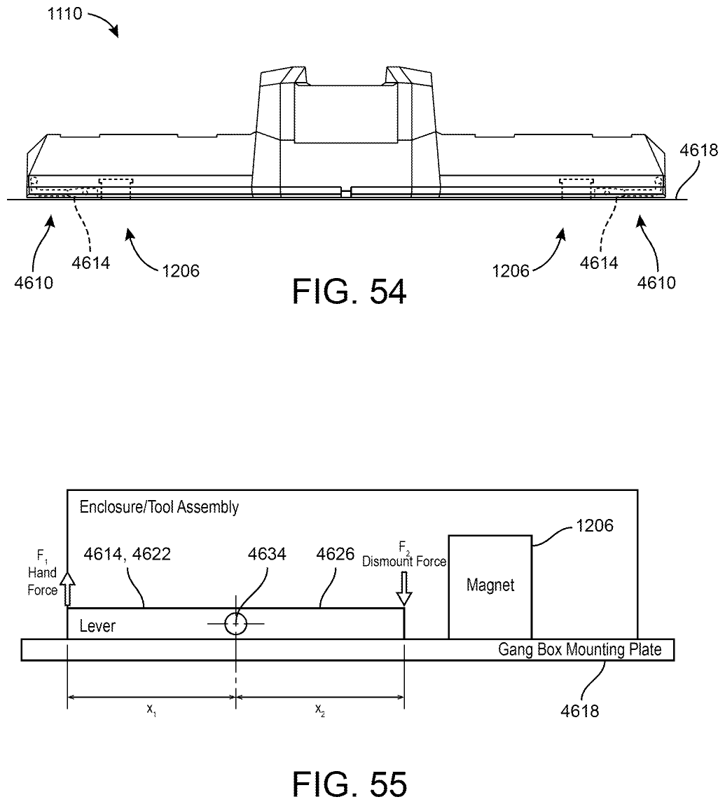

FIGS. 52-57 illustrate a magnet assembly 4610 according to another embodiment for use with the charging station 1110 described above. The magnet assembly 4610 is similar to the magnet assembly 1610 with like features being represented with like reference numerals. The magnet assembly 4610 includes a plurality of magnet assemblies 1206 and at least one actuator 4614. In the illustrated embodiment, an actuator 4614 is positioned on each side of the housing 1122 (i.e., one on the left side and one on the right side). Adjacent each actuator 4614 is two magnet assemblies 1206. In the illustrated embodiment, the magnet assembly 4610 includes four magnet assemblies 1206 (i.e., one adjacent each corner of the back housing 1130). The magnet assemblies 1206 are similar to the magnet assemblies 1206 described above. Specifically, as shown in FIG. 53, each magnet assembly 1206 includes at least one magnet 1210 sandwiched between two billets 1214. The billets 1214 extend through the openings 1218 in the back housing 1130 to engage a mating surface 4618 (FIG. 54).

With continued reference to FIG. 53, each actuator 4614 includes a grip portion 4622 and lever portions 4626 that extend from the grip portion 4622 to define a C-shaped handle. In some embodiments, the actuators 4614 are defined as wire formed handles or sheet metal levers. In further embodiments, the actuators 4614 may be formed with plastic, metal, or through an injection molding/casting process. The grip portions 4622 extend into openings 4630 between the front and back housings 1126, 1130 that is accessible to a user. The end of each lever portion 4626 is positioned adjacent a magnet assembly 1206. Each actuator 4614 is pivotable about a pivot axis 4634 that extends perpendicular to the direction of the length L of the charging station 1110. Specifically, the actuators 4614 are pivotable about a pin 4638 that is supported by the housing 1122. In contrast to the magnet assembly 1610 described above, the actuator 4614 is separate from the magnet assemblies 1206. In other words, the actuator 4614 is moveable independently of the magnet assemblies 1206.

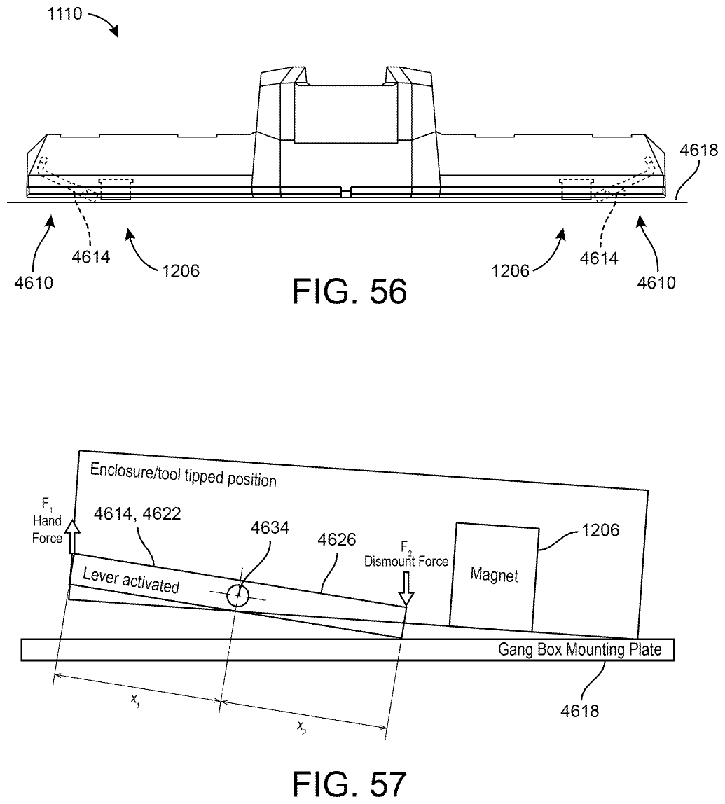

With reference to FIGS. 54-57, the actuators 4614 are moveable between a first, mounting position (FIGS. 54 and 55), and a second, dismount position (FIGS. 56-57), to remove the charging station 1110 from a surface of the gang box 10 or other mating surface 4618. A user may grab the grip portion 4622 of one of the actuators 4614 and pivot the actuator 4614 clockwise (as viewed from FIG. 54) to pull the actuator 4614 away from the mating surface 4618 and towards the front housing 1126. As the actuator 4614 is pulled towards the front housing 1126, the ends of the lever portions 4626 act as a lever finger and engage the mating surface 4618 to disengage the magnets 1210 and the billets 1214 from the mating surface 4618. As the actuator 4614 is moved away from the mating surface 4618, the billets 1214 begin to uncouple form the mating surface 4618. When the actuator 4614 is in the second position, the billets 1214 are completely decoupled from the mating surface 4618 allowing the user to remove the charging station 1110 from the mating surface 4618. The same process described above, may be carried out on either of the actuators 4614.

In some embodiments, when the charging station 1110 is not mounted to a mating surface 4618 a biasing member (e.g., a spring) may bias the actuator 4614 into the dismount position. In other embodiments, the biasing member may bias the actuator 4614 into the mount position. However, as the magnet assemblies 1206 mate with the mating surface 4618, the mating surface 4618 pushes against the ends of the lever portions 4626 of the actuators 4614 against the bias of the biasing member to position the actuator 4614 into the mounting position. In this way, the grip portion 4622 of the actuator 4614 is automatically moved to a position in which a user can easily access the grip portion 4622 to remove the charging station 1110 from the mating surface 4618 if needed.

As illustrated in FIG. 55, the pivot axis 4634 acts as a fulcrum for the lever portions 4626 of the actuators 4614. As such, a first distance X1 is defined between the grip portion 4622 and the pivot axis 4634 and a second distance X2 is defined between the pivot axis 4634 and the ends of the lever portions 4626. It should be noted that the distances X1 and X2 may be varied to change the force and distance required by a user to move the actuator 4614 from the first position to the second position to uncouple the magnet assemblies 1206 form the mating surface 4618. For example, increasing the distance X1 decreases the force required by a user to remove the magnet assemblies 1206 from the mating surface 4618. However, increasing X1 also increases the distance a user must move the actuator 4614 away from the mating surface 4618 to remove the magnet assemblies 1206 from the mating surface 4618. In light of the above, there is an optimal position of the pivot axis 4634. For example, in the illustrated embodiment, X1 is 50 millimeters, X2 is 8 millimeters which requires a user to move the actuator 4614 a total of 4 millimeters in a direction perpendicular to the mating surface 4618 and pivot the actuator 4614 approximately 30 degrees in a clockwise direction. As such, in the illustrated embodiment, the distance X1 is greater than the distance X2. In other embodiments, X1 and X2 may be different lengths to vary the force and distance required to move the actuator 4614 in order to remove the charging station 110 from a gang box 10 or mating surface 4618.

In further embodiments, the magnet assembly 4610 may be used with any of the charging stations 110, 310, 1110, 1310, 1410, 2110, 3110 describe above. The magnet assembly 4610 may support any of the charging stations 110, 310, 1110, 1310, 1410, 2110, 3110 from a gang box or other mating surface. In other embodiments, the magnet assembly 4610 may be used with non-charging stations or accessories. For example the charging station may be supported by a tool box, a battery pack, a power charger, a power tool, an accessory carrier or the like.

Providing a magnet assembly 4610 including an actuator 4614 supported by the housing 1122 allows for tool-less mounting and dismounting of a charging station 1110 from a gang box 10 or other mating surface 4618.

Various features and advantages are set forth in the following claims.

What is claimed is:

1. A charging station comprising:
a housing defining a forward side and a rear side opposite the forward side;
a charging port disposed on the housing, the charging port including a battery receptacle to receive and charge a battery pack; and
a magnet assembly disposed on the rear side of the housing, the magnet assembly configured to support the housing from a mating surface.

2. The charging station of claim 1, wherein the magnet assembly includes an actuator that is moveable between a first position, in which the magnet assembly is coupled to the mating surface to support the housing and a second position, in which the magnet assembly is uncoupled from the mating surface.

3. The charging station of claim 2, wherein the actuator is pivotable about a pivot axis between the first position and the second position.

4. The charging station of claim 1, wherein the housing includes a front housing, a rear housing, and an opening therebetween.

5. The charging station of claim 4, wherein the magnet assembly includes an actuator positioned within the opening.

6. The charging station of claim 1, wherein the magnet assembly includes at least one magnet and at least one billet.

7. A magnet assembly to couple a module to a mating surface, the magnet assembly comprising:
a magnet;
a billet; and
an actuator moveable between a first position, in which the billet engages the mating surface to support the charging station and a second position, in which the billet is disengaged from the mating surface.

8. The magnet assembly of claim 7, wherein the actuator moves between the first and second position independently of either the billet or the magnet.

9. The magnet assembly of claim 7, wherein the billet is a first billet, and wherein the magnet assembly further comprises a second billet.

10. The magnet assembly of claim 9, wherein the magnet assembly is positioned between the first and second billets.

11. The magnet assembly of claim 7, wherein the actuator pivots about a pivot axis between the first and second positions.

12. The magnet assembly of claim 7, wherein the actuator is biased to the second position.

13. The magnet assembly of claim 7, wherein the actuator applies a force greater than 30 pounds to the mating surface when moved from the first position to the second position.

14. A charging station comprising:
a housing defining a front housing and a rear housing opposite the front housing;
a charging port disposed on the housing, the charging port including a battery receptacle configured to receive and charge a battery pack; and
a magnet assembly configured to support the housing from a mating surface, the magnet assembly including,
a magnet; and
an actuator moveable between a first position, in which the magnet assembly engages the mating surface to support the charging station and a second position, in which the magnet assembly is disengaged from the mating surface.

15. The charging station of claim 14, wherein the actuator is pivotable between the first and second positions about a pivot axis.

16. The charging station of claim 15, wherein the pivot axis is parallel to the mating surface.

17. The charging station of claim 15, wherein the actuator includes a grip portion that extends from the housing and a lever portion.

18. The charging station of claim 17, wherein the pivot axis extends through the lever portion, wherein a first distance is defined between the grip portion and the pivot axis and a second distance is defined between the pivot axis and an end of the lever portion, wherein the first distance is greater than the second distance.

19. The charging station of claim 14, wherein the magnet assembly further includes a billet that extends through an opening in the rear housing to engage the mating surface.

20. The charging station of claim 14, wherein the actuator moves from the first position to the second position in a direction away from the mating surface.
